(19) United States
(12) Patent Application Publication
(10) Pub. No.: US 2026/0039278 A1
(43) Pub. Date: Feb. 5, 2026

(54) ACTIVE COMPENSATION DEVICE PROVIDING ELECTROMAGNETIC WAVE NOISE DATA

(71) Applicants: EM CORETECH INC., Ulsan (KR); UNIST(ULSAN NATIONAL INSTITUTE OF SCIENCE AND TECHNOLOGY), Ulsan (KR)

(72) Inventors: Jin Gook KIM, Ulsan (KR); Sang Yeong JEONG, Ulsan (KR)

(21) Appl. No.: 19/358,457

(22) Filed: Oct. 15, 2025

Related U.S. Application Data
(63) Continuation-in-part of application No. 18/548,347, now Pat. No. 12,456,920.

(30) Foreign Application Priority Data
Jun. 4, 2021 (KR) 10-2021-0073037
Sep. 30, 2021 (KR) 10-2021-0129812

(51) Int. Cl. H03H 11/04; H03K 5/1252

(52) U.S. Cl. CPC H03H 11/04; H03K 5/1252

(57) ABSTRACT

An active compensation device is provided. An active compensation device includes an integrated sensing/compensation unit configured to generate a sensing signal corresponding to at least one of common-mode noise and differential-mode noise on at least two high-current paths, and a compensation control unit including a negative impedance converter and configured to generate a compensation signal corresponding to the sensing signal and provide the compensation signal to the integrated sensing/compensation unit. The compensation control unit further includes a stabilization unit configured to prevent oscillation caused by the sensed noise.

### TECHNICAL FIELD

Embodiments of the present disclosure relate to an active compensation device for compensating for a noise current and/or a noise voltage generated in a common mode on two or more high-current paths connecting two devices to each other.

### BACKGROUND ART

In general, electrical devices such as household electrical appliances, industrial electrical appliances, or electric vehicles emit noise during operation. For example, noise may be emitted through a power line due to a switching operation of a power conversion device in an electronic device. When such noise is neglected, not only it is harmful to the human body, but also it causes malfunctions in surrounding parts and other electronic devices. As such, electromagnetic interference that an electronic device exerts on other devices is referred to as electromagnetic interference (EMI), and, among them, noise transmitted through wires and substrate wires is referred to as conducted emission (CE) noise.

In order to ensure that electronic devices operate without causing malfunctions in peripheral components and other devices, the amount of EMI noise emission is strictly regulated in all electronic products. Accordingly, most of the electronic products essentially include a noise reduction device (e.g., an EMI filter) that reduces an EMI noise current, in order to satisfy regulations on the noise emission amount. For example, an EMI filter is essentially included in white goods such as an air conditioner, electric vehicles, airplanes, energy storage systems (ESSs), etc. The related-art EMI filter uses a common-mode (CM) choke to reduce CM noise among CE noise. The CM choke is a passive filter and serves to suppress a CM noise current.

Meanwhile, in a high-power/high-current system, the size or number of common mode chokes needs to be increased in order to prevent magnetic saturation of a CM choke and maintain noise reduction performance. Accordingly, the size and price of EMI filters for high-power products are greatly increased.

### DISCLOSURE

### Technical Problem

Recently, in order to overcome the above-described disadvantages of passive electromagnetic interference (EMI) filters, interest in development of active EMI filters that compensate for noise with a current/voltage generated through an amplifier is increasing.

However, existing active EMI filters only compensate for EMI noise through current/voltage compensation, and it is fundamentally difficult for them to collect information about the noise.

The present disclosure has been made in an effort to improve the above issues, and provides an active compensation device capable of providing information about EMI noise as digital noise data.

However, this objective is merely illustrative, and the scope of the present disclosure is not limited thereto.

### Technical Solution

An active compensation device for actively compensating for noise generated in a common mode on each of at least two high-current paths according to an embodiment of the present disclosure may include: a sensing unit configured to generate an output signal corresponding to a common-mode noise signal on the high-current path; an integrated circuit (IC) unit including an amplification unit configured to output an amplified signal obtained by amplifying the output signal, and a digital circuit unit configured to output noise data into which the output signal is digitally converted; and a compensation unit configured to draw a compensation current out of the high-current path or generate a compensation voltage on the high-current path, based on the amplified signal, and the noise data may be provided to an external device.

According to an embodiment, the IC unit may be composed of a single IC chip, and the single IC chip may include an input terminal to receive the output signal of the sensing unit as an input, a first output terminal to output the amplified signal, and second output terminals to output the noise data.

According to an embodiment, the digital circuit unit may include: an analog-to-digital converter; and an input buffer configured to receive the output signal and attenuate the output signal into a low-voltage analog signal that is usable for the analog-to-digital converter.

According to an embodiment, the IC unit may further include a voltage controlled oscillator configured to generate by itself a clock signal for controlling an internal circuit of the analog-to-digital converter.

According to an embodiment, the IC unit may control an operation of the amplification unit based on a digital signal generated by the digital circuit unit or the noise data.

According to an embodiment, the IC unit may further include a first digital circuit unit configured to digitally convert an input signal of the amplification unit to generate first noise data, and a second digital circuit unit configured to digitally convert an output signal of the amplification unit to generate second noise data.

Other aspects, features, and advantages other than those described above will be apparent from the following drawings, claims, and detailed description.

### Advantageous Effects

According to various embodiments of the present disclosure as described above, electromagnetic interference (EMI) noise data may be collected while canceling the EMI noise by using an active EMI filter.

According to various embodiments of the present disclosure, noise data may be extracted and collected from an active EMI filter, and used for various purposes. For example, noise data output from an active EMI filter according to an embodiment of the present disclosure may be monitored to identify a change in state or an emergency situation. Also, the noise data may be utilized for big data processing.

In some embodiments, the scope of the present disclosure is not limited by these effects.

### DESCRIPTION OF DRAWINGS

FIG. 1 schematically illustrates a configuration of a system including an active compensation device 100 according to an embodiment of the present disclosure.

FIG. 2 illustrates a more detailed example of the embodiment illustrated in FIG. 1, and schematically illustrates an active compensation device 100A according to an embodiment of the present disclosure.

FIG. 3 illustrates a detailed example of an integrated circuit (IC) unit 500, according to various embodiments of the present disclosure.

FIG. 4 illustrates an input buffer 510-1 as an example of an input buffer 510 in an embodiment.

FIG. 5 illustrates an input buffer 510-2 as another example of the input buffer 510 in an embodiment.

FIG. 6 illustrates an example of an analog-to-digital converter 520 in an embodiment.

FIG. 7 illustrates a more detailed example of the embodiment illustrated in FIG. 2, and schematically illustrates an active compensation device 100A-1 according to an embodiment of the present disclosure.

FIG. 8 illustrates a more detailed example of the embodiment illustrated in FIG. 1, and schematically illustrates an active compensation device 100B according to an embodiment of the present disclosure.

FIG. 9 schematically illustrates an active compensation device 100C according to another embodiment of the present disclosure.

FIG. 10 schematically illustrates an active compensation device 100D according to another embodiment of the present disclosure.

FIG. 11 illustrates a more detailed example of the embodiment illustrated in FIG. 1, and schematically illustrates an active compensation device 100E according to an embodiment of the present disclosure.

FIG. 12 schematically illustrates a configuration of a voltage compensation system including an active compensation device according to an embodiment of the present disclosure.

FIG. 13 illustrates a more detailed example of the active compensation device of FIG. 12.

FIG. 14 illustrates a more detailed example of a choke coil included in an integrated sensing/compensation unit.

FIGS. 15A to 15E illustrate other more detailed examples of a choke coil.

FIGS. 16A and 16B illustrate an operation in which an active compensation device according to an embodiment compensates for noise.

FIG. 17 illustrates an equivalent circuit of the voltage compensation system of FIG. 12 according to an embodiment of the present disclosure.

FIG. 18 illustrates a detailed example of a circuit of an active compensation device according to an embodiment of the present disclosure.

FIG. 19 is a graph comparing oscillation stability of the circuit illustrated in FIG. 18.

FIGS. 20A and 20B schematically illustrate a structure of an active compensation device according to an embodiment of the present disclosure.

FIG. 21 schematically illustrates a structure of an active compensation device according to another embodiment of the present disclosure.

FIG. 22 schematically illustrates a configuration of a system including an active compensation device according to another embodiment of the present disclosure.

FIG. 23 schematically illustrates a detailed example of the active compensation device illustrated in FIG. 22 according to an embodiment of the present disclosure.

FIG. 24 illustrates a detailed example of an integrated circuit (IC) unit according to various embodiments of the present disclosure.

### BEST MODE

An active compensation device for actively compensating for noise generated in a common mode on each of at least two high-current paths according to an embodiment of the present disclosure may include: a sensing unit configured to generate an output signal corresponding to a common-mode noise signal on the high-current path; an integrated circuit (IC) unit including an amplification unit configured to output an amplified signal obtained by amplifying the output signal, and a digital circuit unit configured to output noise data into which the output signal is digitally converted; and a compensation unit configured to draw a compensation current out of the high-current path or generate a compensation voltage on the high-current path, based on the amplified signal, and the noise data may be provided to an external device.

### MODE FOR INVENTION

As the present disclosure allows for various changes and numerous embodiments, particular embodiments will be illustrated in the drawings and described in detail. The effects and features of the present disclosure and methods of achieving them will become clear with reference to the embodiments described in detail below with the drawings. However, the present disclosure is not limited to the embodiments disclosed below, and may be implemented in various forms.

Hereinafter, embodiments of the present disclosure will be described in detail with reference to the accompanying drawings, and the same or corresponding components will be denoted by the same reference numerals when described with reference to the accompanying drawings, and thus, their descriptions that are already provided will be omitted.

In the following embodiments, terms such as “first,” “second,” etc., are used only to distinguish one component from another, and such components must not be limited by these terms.

In the following embodiments, the singular expression also includes the plural meaning as long as it is not inconsistent with the context.

In the following embodiments, the terms “comprises,” “includes,” “has”, and the like used herein specify the presence of stated features or components, but do not preclude the presence or addition of one or more other features or components.

For convenience of description, the magnitude of components in the drawings may be exaggerated or reduced. For example, each component in the drawings is illustrated to have an arbitrary size and thickness for ease of description, and thus the present disclosure is not limited to the drawings.

In the following embodiments, when a component, unit, block, or module is referred to as being connected to another component, unit, block, or module, they may be directly connected to each other, or may be indirectly connected to each other with still another component, unit, block, or module therebetween.

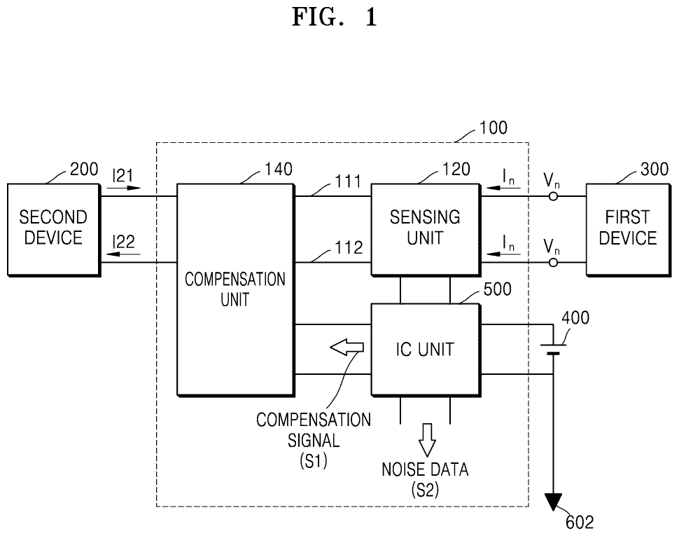

FIG. 1 schematically illustrates a configuration of a system including an active compensation device 100 according to an embodiment of the present disclosure. The active compensation device 100, may actively compensate for noise currents Iₙ (e.g., electromagnetic interference (EMI) noise currents) and/or a noise voltage (e.g., an EMI noise voltage) generated in a common mode (CM) on two or more high-current paths 111 and 112 from a first device 300.

Referring to FIG. 1, the active compensation device 100 may include a sensing unit 120, an integrated circuit (IC) unit 500, and a compensation unit 140.

In some embodiments, the first device 300 may be various types of devices using power supplied by a second device 200. For example, the first device 300 may be a load driven by using power supplied by the second device 200. In addition, the first device 300 may be a load (e.g., an electric vehicle) that stores energy by using power supplied by the second device 200 and is driven by using the stored energy. However, the present disclosure is not limited thereto.

In some embodiments, the second device 200 may be various types of devices for supplying power to the first device 300 in the form of current and/or voltage. For example, the second device 200 may be a device for generating and supplying power or may be a device for supplying power generated by another device (e.g., an electric vehicle charging device). In some embodiments, the second device 200 may also be a device for supplying stored energy. However, the present disclosure is not limited thereto. A power conversion device may be located on the side of the first device 300. For example, the CM noise currents In may be generated on the high-current paths 111 and 112 by a switching operation of the power conversion device. Alternatively, for example, a noise current leaked from the side of the first device 300 may flow into the high-current paths 111 and 112 through the second device 200 via the ground (e.g., reference potential 1), and thus, the noise currents Iₙ may be generated.

The noise currents Iₙ generated in the same direction on the high-current paths 111 and 112 may be referred to as CM noise currents. In addition, a CM noise voltage Vₙ may refer to a voltage generated between the ground (e.g., reference potential 1) and the high-current paths 111 and 112, rather than a voltage generated between the high-current paths 111 and 112.

For example, the side of the first device 300 may correspond to a noise source, and the side of the second device 200 may correspond to a noise receiver.

The two or more high-current paths 111 and 112 may be paths that transfer power supplied by the second device 200, i.e., the high currents I21 and I22, to the first device 300, and may be, for example, power lines. For example, the two or more high-current paths 111 and 112 may be a live line and a neutral line, respectively. At least portions of the high-current paths 111 and 112 may pass through the compensation device 100. High currents 121 and 122 may be alternating currents having a frequency of a second frequency band. The second frequency band may be, for example, between 50 Hz and 60 Hz.

In addition, the two or more high-current paths 111 and 112 may be paths through which the noise currents Iₙ are transferred from the first device 300 to the second device 200. Alternatively, the two or more high-current paths 111 and 112 may be paths where the noise voltage Vₙ is generated with respect to the ground (e.g., reference potential 1).

The noise currents Iₙ or the noise voltage Vₙ may be input in a CM to each of the two or more high-current paths 111 and 112. The noise current Iₙ may be a current unintentionally generated in the first device 300 due to various causes. For example, the noise current Iₙ may be a noise current due to a parasitic capacitance between the first device 300 and the surrounding environment. Alternatively, the noise current Iₙ may be a noise current generated by a switching operation of a power conversion device of the first device 300. The noise current Iₙ and the noise voltage Vₙ may have a frequency of a first frequency band. The first frequency band may be higher than the above-described second frequency band. The first frequency band may be, for example, between 150 KHz and 30 MHz.

Although the drawing illustrates that the noise currents Iₙ and the noise voltage Vₙ are at nodes on the high-current paths 111 and 112 between the first device 300 and the sensing unit 120, the terms ‘noise current’ and ‘noise voltage’ as used herein are not limited thereto and may respectively refer to a voltage and a current that may be generated in a CM with the first frequency throughout the high-current paths 111 and 112.

Meanwhile, the two or more high-current paths 111 and 112 may include two paths as illustrated in FIG. 1, and may also include three paths (e.g., a three-phase three-wire power system), or four paths (e.g., a three-phase four-wire power system). The number of high-current paths 111 and 112 may vary depending on the type and/or form of power used by the first device 300 and/or the second device 200.

The sensing unit 120 may sense the noise currents Iₙ on the two or more high-current paths 111 and 112 and generate an output signal corresponding to the noise currents Iₙ, toward the IC unit 500. That is, the sensing unit 120 may refer to a unit configured to sense the noise currents Iₙ on the high-current paths 111 and 112. Although at least portions of the high-current paths 111 and 112 may pass through the sensing unit 120 to sense the noise currents Iₙ, a portion of the sensing unit 120 where the output signal is generated by the sensing may be insulated from the high current paths 111 and 112. For example, the sensing unit 120 may be implemented as a sensing transformer. The sensing transformer may sense the noise currents Iₙ on the high-current paths 111 and 112 while being insulated from the high-current paths 111 and 112.

The IC unit 500 may be electrically connected to the sensing unit 120 to generate a compensation signal S1 corresponding to an amplified signal of the output signal output by the sensing unit 120, and also generate noise data S2 corresponding to a digital signal of the output signal. In the present disclosure, ‘amplification’ may refer to adjusting the magnitude and/or phase of a target to be amplified. The IC unit 500 may be implemented by various units and may include an active element.

According to various embodiments of the present disclosure, the IC unit 500 may output the compensation signal S1 for canceling noise to the compensation unit 140, and output the digital data S2 representing the noise to the outside.

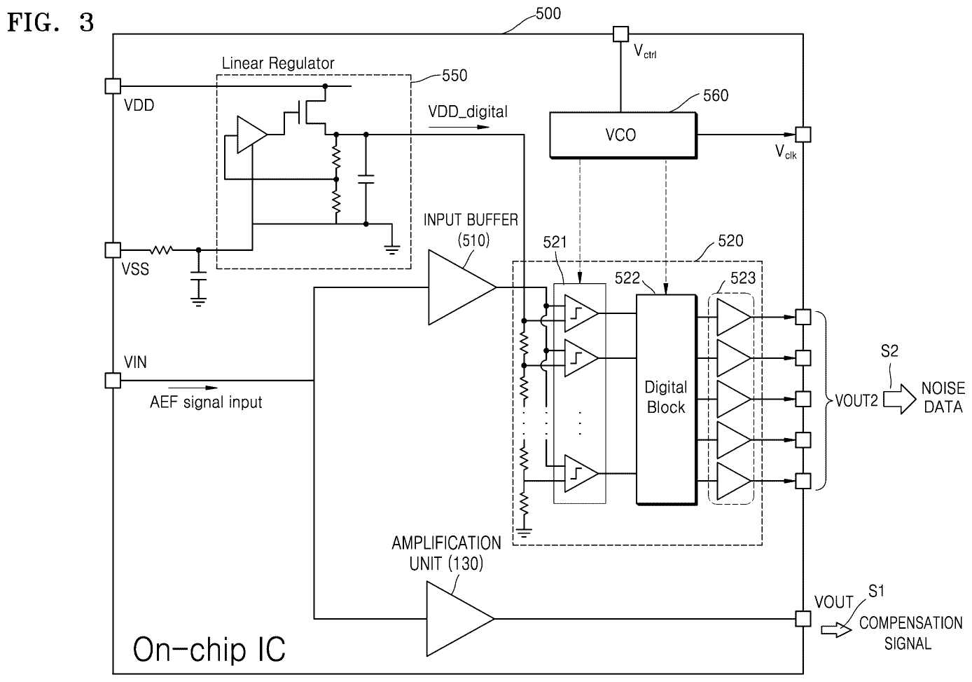

In various embodiments of the present disclosure, the IC unit 500 may include a circuit configured to convert an output signal (i.e., an analog signal corresponding to noise) output from the sensing unit 120 into a digital signal. In various embodiments, the IC unit 500 may output the noise data S2 generated based on the digital signal to the outside. In addition, the IC unit 500 may include an amplification unit configured to amplify an output signal (i.e., an analog signal corresponding to noise) output from the sensing unit 120. The IC unit 500 may output an analog signal amplified through the amplification unit, as the compensation signal S1, to the compensation unit 140. An example of the detailed configuration of the IC unit 500 will be described below with reference to FIGS. 3 to 6.

For example, the noise data S2 output from the active compensation device 100 may be transferred to and stored in a data storage, or may be transferred to a waveform display device. For example, the noise data S2 may be monitored to identify a change in state or an emergency situation. The noise data S2 may be used for big data processing or artificial intelligence technology.

Meanwhile, the IC unit 500 may receive power supplied from a third device 400 separate from the first device 300 and/or the second device 200, amplify an output signal output by the sensing unit 120 to generate an amplified current/voltage as the compensation signal S1, and generate the noise data S2 based on the output signal. Here, the third device 400 may be a device for receiving power from a power source separate from the first device 300 and the second device 200 to generate input power of the IC unit 500. Optionally, the third device 400 may be a device for receiving power from any one of the first device 300 and the second device 200 to generate input power of the IC unit 500.

The IC unit 500 may output an amplified voltage or an amplified current as the compensation signal S1 to the side of the compensation unit 140. The compensation signal S1 is input to the compensation unit 140. The compensation unit 140 may generate a compensation voltage or a compensation current based on the input compensation signal (the amplified voltage or amplified current).

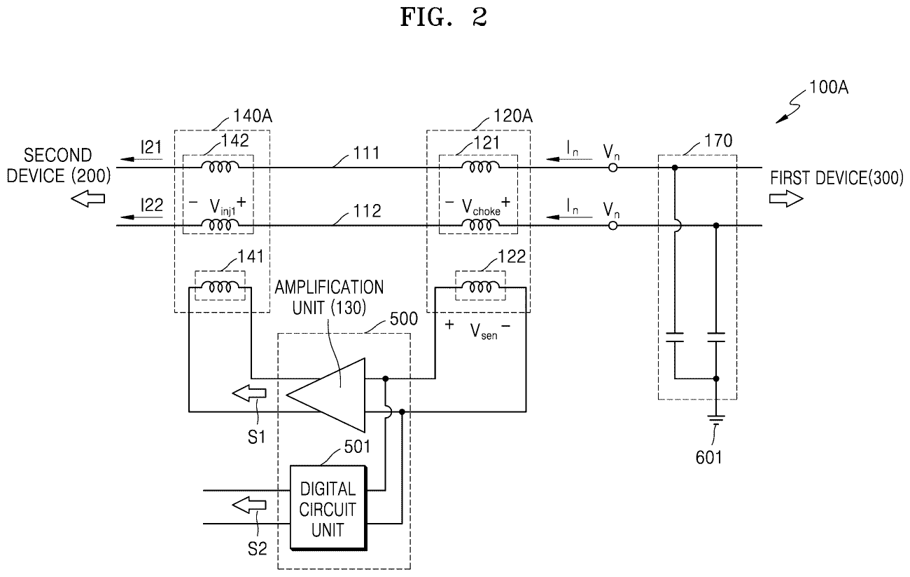

According to an embodiment, the compensation unit 140 may generate compensation voltages in series on the high-current paths 111 and 112 based on the amplified voltage output from the IC unit 500. An output side of the compensation unit 140 may generate the compensation voltages in series on the high-current paths 111 and 112, but may be insulated from the IC unit 500. For example, the compensation unit 140 may include a compensation transformer for the insulation. For example, a compensation signal output from the IC unit 500 may be applied to a primary side of the compensation transformer, and a compensation voltage based on the compensation signal may be generated on a secondary side of the compensation transformer. The compensation voltage may have an effect of suppressing the noise currents Iₙ flowing through the high-current paths 111 and 112. In this case, the compensation unit 140 may correspond to voltage compensation. The voltage compensation will be described in detail below with reference to FIGS. 2, 7, 10, and 11.

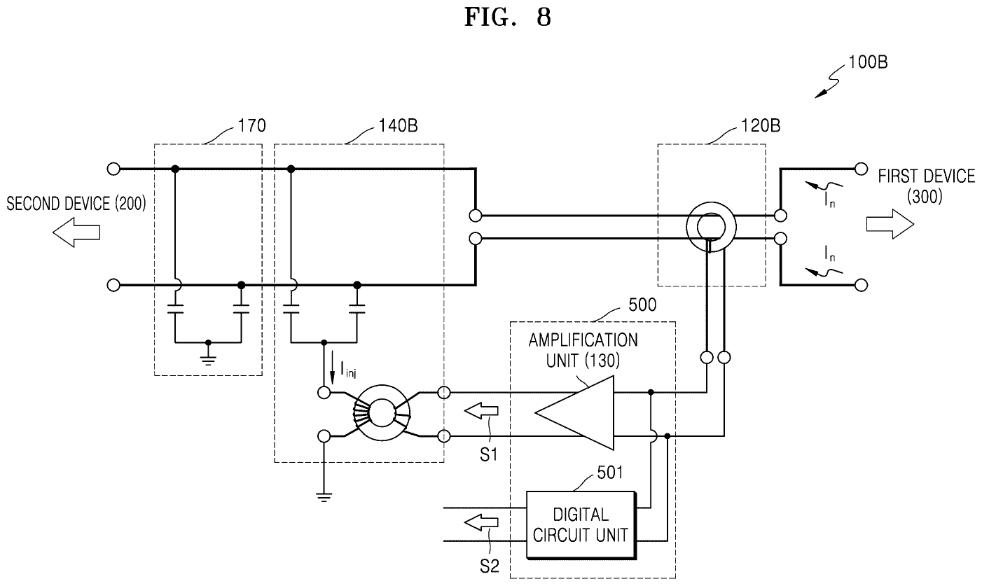

According to another embodiment, the compensation unit 140 may generate a compensation current based on the amplified current output from the IC unit 500. The compensation current may be injected into or drawn out of the high-current paths 111 and 112 to cancel or reduce the noise currents Iₙ on the high-current paths 111 and 112. In this case, the compensation unit 140 may correspond to current compensation. The current compensation will be described in detail below with reference to FIGS. 8, 9, and 10. Meanwhile, the output side of the compensation unit 140 may be connected to the high-current paths 111 and 112 to allow the compensation current to flow to the high-current paths 111 and 112, but may be insulated from the IC unit 500. For example, the compensation unit 140 may include a compensation transformer for the insulation.

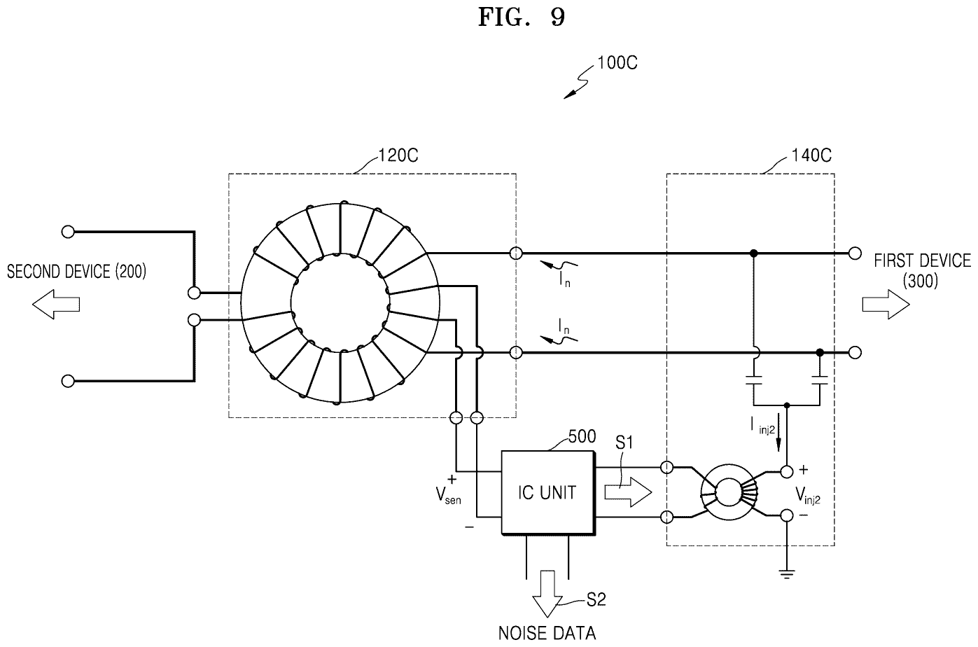

The compensation unit 140 may be of a feedforward type that compensates for noise input from the side of the first device 300 at a front end thereof, which is a power source side. However, the present disclosure is not limited thereto, and the active compensation device 100 may include a feedback-type compensation unit that compensates for noise at a rear end thereof (see FIG. 9).

FIG. 2 illustrates a more detailed example of the embodiment illustrated in FIG. 1, and schematically illustrates an active compensation device 100A according to an embodiment of the present disclosure. The active compensation device 100A may include a sensing unit 120A, the IC unit 500, and a compensation unit 140A.

In FIG. 2 and the following drawings, a reference potential 602 (reference potential 2) of the first device 300, the second device 200, the third device 400, and the IC unit 500 may be omitted. That is, the high-current paths 111 and 112 at the front end of the active compensation device 100A (e.g., the side of the compensation unit 140A) may be connected to a power line of the second device 200, and the high-current paths 111 and 112 at the rear end (e.g., the side of the sensing unit 120A) may be connected to a power line of the first device 300. In addition, although not illustrated, the IC unit 500 may receive power supplied from the third device 400 to drive internal active elements of the IC unit 500.

According to an embodiment, the above-described sensing unit 120 may include a sensing transformer 120A.

The sensing transformer 120A may be a unit for sensing a voltage (e.g., V_{choke}) induced in both ends of the sensing transformer 120A due to the noise currents Iₙ or the noise current Iₙ on the high current paths 111 and 112, while being insulated from the high current path 111 and 112.

The sensing transformer 120A may include a primary side 121 arranged on the high-current paths 111 and 112, and a secondary side 122 connected to an input terminal of the IC unit 500. The sensing transformer 120A may generate an induced current or an induced voltage Vₛₑₙ directed to the secondary side 122 (e.g., a secondary winding) based on magnetic flux densities induced due to the noise currents Iₙ, at the primary side 121 (e.g., a primary winding) arranged on the high-current paths 111 and 112. The primary side 121 of the sensing transformer 120A may be, for example, a winding in which each of the first high-current path 111 and the second high-current path 112 is wound around one core.

In detail, the sensing transformer 120A may be configured such that the magnetic flux density induced due to the noise current Iₙ on the first high-current path 111 (e.g., a live line) and the magnetic flux density induced due to the noise current Iₙ on the second high-current path 112 (e.g., a neutral line) are overlapped (or reinforced) with each other. Here, the high currents 121 and 122 also flow through the high-current paths 111 and 112, and thus, the sensing transformer 120A may be configured such that a magnetic flux density induced due to the high current 121 on the first high-current path 111 and a magnetic flux density induced due to the high current 122 on the second high-current path 112 cancel each other. In addition, for example, the sensing transformer 120A may be configured such that magnitudes of the magnetic flux densities, which are induced due to the noise currents Iₙ of the first frequency band (e.g., a band between 150 KHz and 30 MHz), are greater than magnitudes of the magnetic flux densities induced due to the high currents 121 and 122 of the second frequency band (e.g., a band between 50 Hz and 60 Hz).

As described above, the sensing transformer 120A may be configured such that the magnetic flux densities induced due to the high currents I21 and I22 may cancel each other and thus only the noise currents Iₙ may be sensed. That is, the voltage Vₛₑₙ induced in the secondary side 122 of the sensing transformer 120A may be a voltage into which the induced voltage (e.g., V_{choke}) in the primary side 121 is converted at a preset ratio.

The induced voltage Vₛₑₙ induced in the secondary side of the sensing transformer 120A may be input to the IC unit 500 as an input signal. That is, the input signal of the IC unit 500 may be a signal proportional to the noise currents Iₙ or the noise voltage Vₙ.

The IC unit 500 may include an amplification unit 130 and a digital circuit unit 501. A signal input to the IC unit 500 may be input to each of the amplification unit 130 and the digital circuit unit 501.

The amplification unit 130 may amplify the input signal (e.g., Vₛₑₙ) and output the amplified signal as the compensation signal S1. The digital circuit unit 501 may output the noise data S2 based on the input signal (e.g., Vₛₑₙ) . Examples of detailed configurations of the IC unit 500 and the digital circuit unit 501 will be described below with reference to FIGS. 3 to 6.

In the present disclosure, ‘amplification’ by the amplification unit 130 may refer to adjusting the magnitude and/or phase of a target to be amplified. The amplification unit 130 may be implemented by various units and may include an active element. In an embodiment, the amplification unit 130 may include a bipolar junction transistor (BJT). For example, the amplification unit 130 may include a plurality of passive elements such as resistors and capacitors, in addition to the BJT. However, the present disclosure is not limited thereto, and a unit for ‘amplification’ described in the present disclosure may be used without limitation as the amplification unit 130 of the present disclosure.

Meanwhile, the reference potential (reference potential 2, 602) of the IC unit 500 and the reference potential (reference potential 1. 601) of the compensation device 100 may be distinguished from each other.

According to an embodiment, the above-described compensation unit 140 may include a compensation transformer 140A.

The compensation transformer 140A may insulate the IC unit 500 including the active element from the high-current paths 111 and 112. The compensation transformer 140A may be a unit for performing voltage compensation by inducing a compensation voltage Vᵢₙⱼ₁ in the high-current paths 111 and 112 based on the compensation signal S1 output from the IC unit 500, while being insulated from the high-current paths 111 and 112.

The compensation transformer 140A may have, for example, a structure in which a wire of a primary side 141 and a wire of a secondary side 142 pass through one core or are wound around one core at least once. The wire of the primary side 141 may be through which the compensation signal S1 output from the IC unit 500 flows, and the wire of the secondary side 142 may correspond to the high-current paths 111 and 112.

The compensation transformer 140A may induce the compensation voltage Vᵢₙⱼ₁ on the high-current paths 111 and 112, which are on the secondary side 142, based on an amplified voltage generated in the primary side 141.

Meanwhile, the active compensation device 100A according to an embodiment of the present disclosure may further include a decoupling capacitor unit 170.

The decoupling capacitor unit 170 may be arranged, for example, between the sensing unit 120 and the first device 300, and may include two Y-capacitors having one ends connected to reference potential 1 601 and the other ends respectively connected to the high-current paths 111 and 112.

FIG. 3 illustrates a detailed example of the IC unit 500, according to various embodiments of the present disclosure. Referring to FIGS. 2 and 3, the IC unit 500 according to an embodiment of the present disclosure may include the amplification unit 130 and the digital circuit unit 501. The digital circuit unit 501 may convert an analog signal, which is an input signal of the IC unit 500, into the digital noise data S2, and may include an input buffer 510 and an analog-to-digital converter (ADC) 520.

The IC unit 500 may further include a linear regulator 550 and a voltage controlled oscillator (VCO) 560. The linear regulator 550 may generate a direct current (DC) low voltage for driving active elements inside the IC unit 500. The VCO 560 may generate a clock signal for controlling an internal circuit of the analog-to-digital converter (ADC) 520.

The IC unit 500 may be physically a single IC chip. According to the present embodiment, the digital noise data S2 and the compensation signal S1 as described above may be generated from one IC chip. In other words, a component (e.g., the digital circuit unit 501) for generating the noise data S2 and the amplification unit 130 for generating the compensation signal S1 may be implemented on one IC chip. However, this is only an embodiment, and in another embodiment, a component for generating noise data and a component for generating a compensation signal may be implemented on one or more different chips or packages.

The IC unit 500 may include an input terminal VIN for receiving an output signal of the sensing unit 120, a first output terminal VOUT for outputting the compensation signal S1, and second output terminals VOUT2 for outputting the digital noise data S2.

As described above, the sensing unit 120 may sense a noise signal (Iₙ or Vₙ) to generate an output signal corresponding to the noise signal. An output signal output from the sensing unit 120 serves as an input signal of the IC unit 500.

The output signal of the sensing unit 120 may be input through the input terminal VIN of the IC unit 500, and then input to each of the amplification unit 130 and the input buffer 510 of the digital circuit unit 501, within the IC unit 500.

The amplification unit 130 may amplify an analog input signal. The amplified analog signal may be output as the compensation signal S1 through the first output terminal VOUT. The compensation signal S1 output through the first output terminal VOUT may be input to the above-described compensation unit 140. Meanwhile, because the compensation signal S1 needs to be sufficiently large, the output voltage of the amplification unit 130 may be designed to correspond to about 12 V, but the present disclosure is not limited thereto.

Meanwhile, a signal input through the input terminal VIN of the IC unit 500 is also input to the digital circuit unit 501 including the input buffer 510 and the analog-to-digital converter (ADC) 520.

According to an embodiment, a noise signal input to the input buffer 510 of the digital circuit unit 501 may be a high-voltage swing of 10 V or greater. Thus, for example, the input buffer 510 may be a high-swing double-diffused metal oxide semiconductor (DMOS) having a sufficient breakdown voltage and performance.

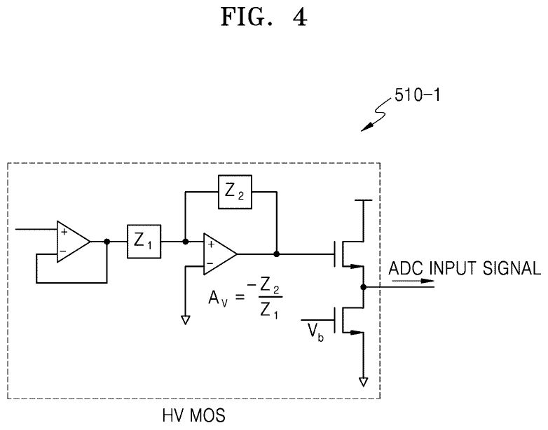

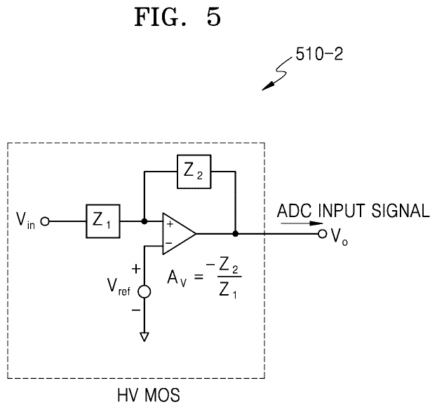

FIG. 4 illustrates an input buffer 510-1 as an example of the input buffer 510 in an embodiment, and FIG. 5 illustrates an input buffer 510-2 as another example of the input buffer 510 in an embodiment. Hereinafter, descriptions of the input buffer 510 are applicable to the input buffers 510, 510-1, and 510-2.

Because the input noise signal may be a high-voltage signal of 10 V or greater, the input buffers 510, 510-1 and 510-2 may be high-voltage (HV) input buffers. For example, a target breakdown voltage of the input buffer 510 may be 12 V, the input impedance may be 100 kohm or greater, and the bandwidth (BW) may correspond to about 30 Mhz. However, the present disclosure is not limited thereto.

The input buffer 510 may serve as an attenuator that minimizes distortion of an input signal and attenuates the input signal into a low-voltage analog signal suitable for the ADC 520. In other words, for example, the input buffer 510 may reduce the amplitude of the input noise signal and output the input noise signal to the ADC 520.

In an embodiment, as illustrated in FIG. 4, the input buffer 510-1 may include multi-stage amplifiers, and in another embodiment, as illustrated in FIG. 5, the input buffer 510-2 may include a one-stage inverting amplifier.

For example, in the input buffer 510-2, when an input signal is Vᵢₙ, an output signal Vₒ may be expressed as Equation 1 below.

$${V}_{o} \approx {V}_{ref} - \frac{{Z}_{2}}{{Z}_{1}} ( {V}_{in} - {V}_{ref} ) \qquad [ Equation 1 ]$$

Meanwhile, an attenuated signal output from the input buffer 510 may be input to the ADC 520 of the digital circuit unit 501. The attenuated signal input to the ADC 520 may correspond to an EMI noise signal. Here, ‘corresponding’ may mean that the magnitude of the EMI noise signal is changed at a preset rate, but is not limited thereto.

The ADC 520 may receive the attenuated signal, convert the attenuated signal into a digital signal, and output the digital noise data S2 based on the digital signal.

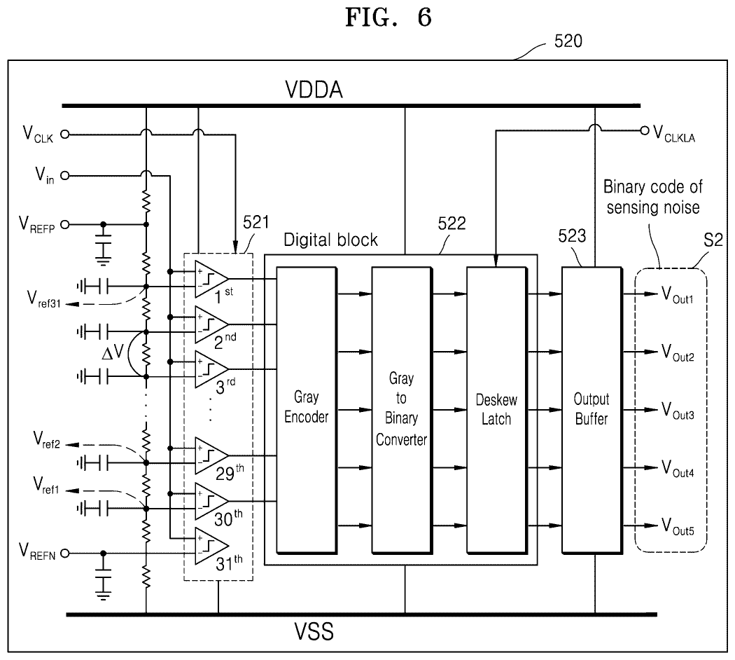

FIG. 6 illustrates an example of the ADC 520 in an embodiment. According to an embodiment, the ADC 520 may include a converter circuit 521, a digital block 522, and/or an output buffer 523.

The converter circuit 521 may be referred to as a data processing core of the ADC 520. For example, the converter circuit 521 may be configured as a flash ADC as illustrated in FIG. 6. The flash ADC may output a digital signal in the form of a thermometer code according to the magnitude of the input analog signal.

However, the converter circuit 521 is not limited to the flash ADC, and may include, for example, a successive-approximation register (SAR) ADC or a sigma-delta ADC, and may be configured as other types of ADCs.

Meanwhile, the digital signal output from the converter circuit 521 may be input to the digital block 522. The digital block 522 may include, for example, a gray encoder, a gray-to-binary converter, and/or a deskew latch, and thus may generate a binary code that minimizes glitches.

For example, the digital block 522 may be a component that processes the digital signal output from the converter circuit 521 to minimize glitches of the digital noise data S2.

The signal output from the digital block 522 may be output through the output buffer 523 as the digital noise data S2 in the form of a binary code representing noise. The noise data S2 may be output as a 5-bit signal, but is not limited thereto. According to an embodiment, the noise data S2 may be output as an 8-bit to 10-bit signal, or a signal with any number of bits.

The noise data S2 may be output to the outside of the active compensation device 100 through the second output terminals VOUT2. The second output terminals VOUT2 may be connected to an external device such as a data storage or a waveform display device. The noise data S2 output to the outside of the active compensation device 100 may be monitored to identify a change in state or an emergency situation. The noise data S2 may be used for big data processing or artificial intelligence technology.

Meanwhile, in an embodiment, a target input voltage level of the analog-to-digital converter 520 may be designed to correspond to 0.3 V to 1.3 V, and the switching frequency may be designed to correspond to about 800 Mhz. However, the present disclosure is not limited thereto. When the target input voltage level is designed to be 0.3 V to 1.3 V, in FIG. 6, V_{REFN} may correspond to 0.3 V and V_{REFP} may correspond to 1.3 V. In addition, in an embodiment, VDDA may be designed to correspond to about 1.8 V, but is not limited thereto.

The IC unit 500 may further include the VCO 560. The VCO 560 may generate a clock signal whose frequency varies depending on an input voltage. The VCO 560 may be embedded in the IC unit 500 such that the active compensation device 100 generates a clock signal by itself without an external clock generator.

For example, the VCO 560 may receive an input voltage from the outside (e.g., the third device 400) through a terminal V_{ctrl} of the IC unit 500. The clock signal generated by the VCO 560 may be transferred to the ADC 520 to be used to control internal circuits.

The linear regulator 550 may generate a DC low voltage for driving the internal circuits of the IC unit 500, such as the ADC 520 and the VCO 560. For example, the linear regulator 550 may receive an input voltage of about 12 V from the outside (e.g., the third device 400) through terminals VSS and VDD of the IC unit 500 and output a DC low voltage of about 1.8 V. However, the present disclosure is not limited thereto. The DC low voltage may be used to drive the internal circuits of the IC unit 500, such as the ADC 520 and the VCO 560.

According to an embodiment of the present disclosure, noise data generated by the digital circuit unit 501 may be used to control the operation of the amplification unit 130 such that the amplification unit 130 operates optimally. For example, the operation of the amplification unit 130 may be controlled based on a digital signal that is an output signal of the converter circuit 521, and may also be controlled based on an output signal (e.g., the noise data S2) of the digital block 522 or the output buffer 523. In this case, the amplification unit 130 may operate differently according to the digital signal or the noise data S2.

For example, the IC unit 500 may further include a control circuit for controlling the amplification unit 130 based on the digital signal or the noise data S2. For example, the control circuit may be connected from an output terminal of the converter circuit 521, the digital block 522, or the output buffer 523 to the amplification unit 130.

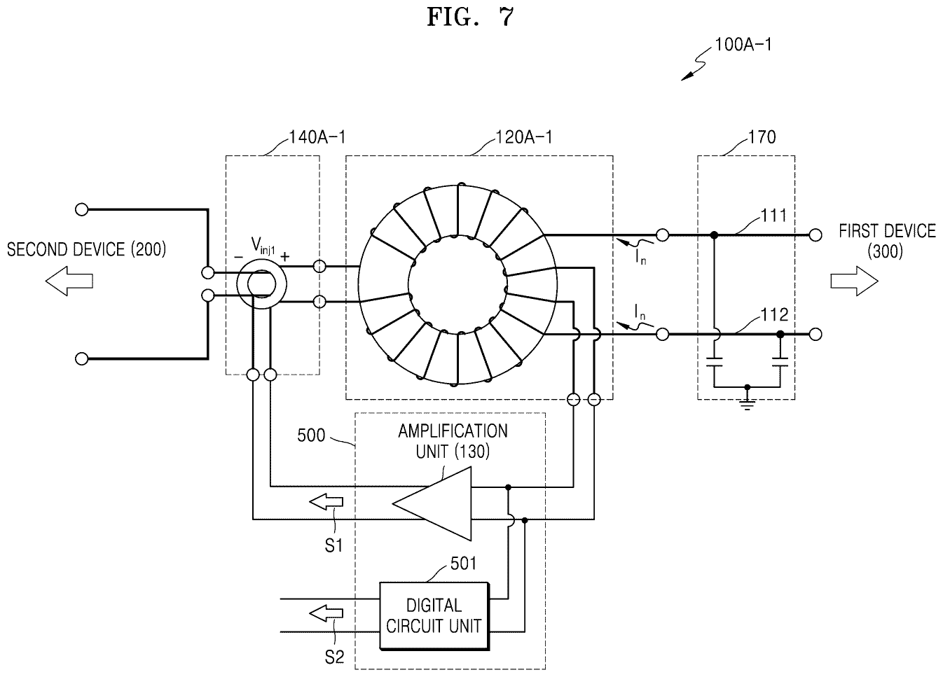

FIG. 7 illustrates a more detailed example of the embodiment illustrated in FIG. 2, and schematically illustrates an active compensation device 100A-1 according to an embodiment of the present disclosure. In FIG. 7, the third device 400 and the reference potential 602 of the IC unit 500 are omitted for convenience of description.

Referring to FIG. 7, the active compensation device 100A-1 may include a sensing unit 120A-1, the IC unit 500, and a compensation transformer 140A-1. The sensing unit 120A-1, the IC unit 500, and the compensation transformer 140A-1 are examples of the sensing units 120 and 120A, the IC unit 500, and the compensation units 140 and 140A described above, respectively.

The active compensation device 100A-1 may sense the noise currents Iₙ input in a CM respectively to two high-current paths 111 and 112 connected to the first device 300, and actively compensate for the noise currents Iₙ with the compensation voltage Vᵢₙⱼ₁.

The sensing unit 120A-1 may be, for example, a sensing transformer in which a secondary side wire is wound around a CM choke around which power lines corresponding to the high-current paths 111 and 112 are wound. The secondary side wire may be connected to the input terminal VIN of the IC unit 500.

When the sensing unit 120A-1 is formed by using the CM choke as described above, the sensing unit 120A-1 may serve as a passive filter with the CM choke, as well as performing functions of sensing and transforming. That is, the sensing transformer formed by additionally winding the secondary side wire around the CM choke may simultaneously function to suppress or block the noise currents Iₙ along with sensing and transforming the noise currents Iₙ.

Meanwhile, the output signal Vₛₑₙ of the sensing unit 120A-1 may be input to the IC unit 500. As described above, the IC unit 500 may generate and output the noise data S2 by converting the output signal Vₛₑₙ into a digital signal, and output the compensation signal S1 (or an amplified signal) based on the output signal Vₛₑₙ. According to an embodiment, the IC unit 500 may control the operation of the amplification unit 130 based on the digital signal or the noise data S2.

The noise data S2 may be stored in a data storage external to the active compensation device 100A-1, and utilized.

The compensation signal S1 may correspond to an input voltage of the compensation transformer 140A-1. The compensation transformer 140A-1 may induce the compensation voltage Vᵢₙⱼ₁ in series on the high-current paths 111 and 112, which are on the secondary side, based on the input voltage applied to the primary side. The compensation voltage Vᵢₙⱼ₁ generated in series on the high-current paths 111 and 112 may have an effect of suppressing the noise currents Iₙ flowing through the high-current paths 111 and 112.

The active compensation device 100A-1 described above is an example of a current-sensing voltage-compensating (CSVC) type that senses the noise currents Iₙ and compensates for the noise currents Iₙ with the compensation voltage Vᵢₙⱼ₁.

FIG. 8 illustrates a more detailed example of the embodiment illustrated in FIG. 1, and schematically illustrates an active compensation device 100B according to an embodiment of the present disclosure. In FIG. 8, the third device 400 and the reference potential 602 of the IC unit 500 are omitted for convenience of description.

Referring to FIG. 8, the active compensation device 100B may include a sensing transformer 120B, the IC unit 500, and a compensation unit 140B. The sensing transformer 120B, the IC unit 500, and the compensation unit 140B are examples of the sensing units 120 and 120A, the IC unit 500, and the compensation unit 140 described above, respectively.

The active compensation device 100B may sense the noise currents Iₙ input in a CM respectively to two high-current paths connected to the first device 300, and actively compensate for the noise currents Iₙ with a compensation current Iᵢₙⱼ.

The sensing transformer 120B may have, for example, a structure in which a primary side wire and a secondary side wire pass through one core or are wound around one core at least once. The primary side wire of the sensing transformer 120B may correspond to a power line that is a high-current path, and the secondary side wire of the sensing transformer 120B may be connected to an input terminal of the IC unit 500. In an embodiment, the volume of the sensing transformer 120B may be minimized by passing the primary side wire and the secondary side wire through the core instead of the CM choke, or by winding the primary side wire and the secondary side wire around the core at least once.

An output signal of the sensing unit 120B may be proportional to the magnitude of the noise current Iₙ.

The output signal of the sensing unit 120B may be input to the IC unit 500. As described above, the IC unit 500 may include the digital circuit unit 501 that generates and outputs the noise data S2 by converting the output signal into a digital signal, and the amplification unit 130 that outputs the compensation signal S1 (or an amplified signal) based on the output signal. According to an embodiment, the IC unit 500 may further include a circuit that controls the operation of the amplification unit 130 based on the digital signal or the noise data S2.

The noise data S2 may be stored in a data storage external to the active compensation device 100B, and utilized.

The compensation signal S1 may be input to the compensation unit 140B. In the present embodiment, the compensation unit 140B may include a compensation transformer and a compensation capacitor unit.

A primary side of the compensation transformer may be connected to the first output terminal VOUT of the IC unit 500, and a secondary side of the compensation transformer may be connected to a high-current path. The compensation transformer may generate, in the secondary side, the compensation current Iᵢₙⱼ to be injected into the high-current path, based on the amplified current (i.e., the compensation signal S1) flowing in the primary side, while insulating the IC unit 500 from the high-current path.

The secondary side of the compensation transformer may be arranged on a path connecting the compensation capacitor unit to a reference potential. That is, one end of the secondary side may be connected to the high-current path through the compensation capacitor unit, and the other end of the secondary side may be connected to the reference potential of the active compensation device 100B.

The current (i.e., a secondary side current) Iᵢₙⱼ obtained through conversion by the compensation transformer may be injected into or drawn out of the high-current path through the compensation capacitor unit, as the compensation current Iᵢₙⱼ. As such, the compensation capacitor unit may provide a path through which the current generated in the secondary side of the compensation transformer flows to each high current. In this way, the active compensation device 100B may reduce EMI noise.

The compensation capacitor unit may include two Y-capacitors (Y-caps) having one ends connected to the secondary side of the compensation transformer and the other ends connected to the high-current path.

The active compensation device 100B described above is an example of a feedforward CSCC type that senses the noise currents Iₙ and compensates for the noise currents Iₙ with the compensation current Iᵢₙⱼ at a front end thereof, which is a power source side.

FIG. 9 schematically illustrates an active compensation device 100C according to another embodiment of the present disclosure. The third device 400 and the reference potential 602 of the IC unit 500 are omitted for convenience of description.

The active compensation device 100C may sense the noise currents Iₙ input in a CM respectively to two high-current paths connected to the first device 300, and actively compensate for the noise currents Iₙ with a compensation current Iᵢₙⱼ₂.

Referring to FIG. 9, the active compensation device 100C may include a sensing unit 120C, the IC unit 500, and a compensation unit 140C. The compensation unit 140C may include a compensation transformer and a compensation capacitor unit.

The sensing unit 120C corresponds to the sensing unit 120A-1 described above with reference to FIG. 7, the IC unit 500 corresponds to the IC unit 500 described above with reference to various embodiments, and the compensation unit 140C corresponds to the compensation unit 140B described above with reference to FIG. 8, and thus, detailed descriptions thereof will be omitted.

The active compensation device 100C is an example of a feedback CSCC type that compensates for the sensed noise currents Iₙ with the compensating current Iᵢₙⱼ₂ at a rear end thereof.

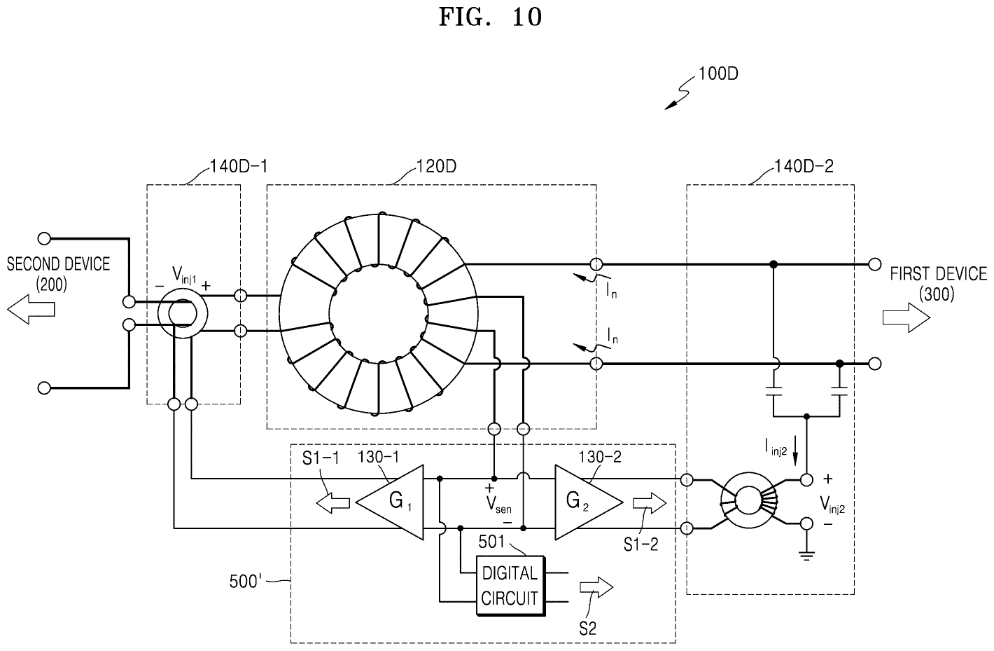

FIG. 10 schematically illustrates an active compensation device 100D according to another embodiment of the present disclosure. The third device 400 and the reference potential 602 of the IC unit 500 are omitted for convenience of description.

The active compensation device 100D may sense the noise currents Iₙ input in a CM respectively to two high-current paths connected to the first device 300, and collectively compensate for the noise currents Iₙ with the compensation voltage Vᵢₙⱼ₁ and the compensation current Iᵢₙⱼ₂.

Referring to FIG. 10, the active compensation device 100D may include a sensing unit 120D, an IC unit 500′, a first compensation unit 140D-1, and a second compensation unit 140D-2. The second compensation unit 140D-2 may include a compensation transformer and a compensation capacitor unit.

The sensing unit 120D corresponds to the sensing unit 120A-1 described above with reference to FIG. 7, the first compensation unit 140D-1 corresponds to the compensation transformer 140A-1 described above with reference to FIG. 7, and the second compensation unit 140D-2 corresponds to the compensation unit 140B described above with reference to FIG. 8, and thus, detailed descriptions thereof will be omitted.

An output signal (e.g., Vₛₑₙ) of the sensing unit 120D may be input to the IC unit 500′. As described above, the IC unit 500′ may generate the noise data S2 by converting and processing the output signal (e.g., Vₛₑₙ) into a digital signal, and output a first compensation signal S1-1 and a second compensation signal S1-2 based on the output signal (e.g., Vₛₑₙ) .

For example, the IC unit 500′ may include a first amplification unit 130-1 that amplifies an input signal (e.g., Vₛₑₙ) to output the first compensation signal S1-1, and a second amplification unit 130-2 that amplifies an input signal (e.g., Vₛₑₙ) to output the second compensation signal S1-2.

According to an embodiment, the IC unit 500′ may control the operation of the first amplification unit 130-1 and/or the second amplification unit 130-2 based on the digital signal or the noise data S2.

The IC unit 500′ including the first amplification unit 130-1, the second amplification unit 130-2, and the digital circuit unit 501 may be physically a single IC chip. For example, the IC unit 500′ may include a 1-1st output terminal for outputting the first compensation signal S1-1 to the first compensation unit 140D-1, and a 1-2nd output terminal for outputting the second compensation signal S1-2 to the second compensation unit 140D-2. However, the present disclosure is not limited thereto.

The first compensation signal S1-1 output from the IC unit 500′ may correspond to an input voltage of the first compensation unit 140D-1. The first compensation unit 140D-1 may be a compensation transformer that induces the compensation voltage Vᵢₙⱼ₁ in series on a high-current path, which is on a secondary side, based on the input voltage applied to a primary side. The compensation voltage Vᵢₙⱼ₁ generated in series on the high-current path may have an effect of suppressing the noise current Iₙ flowing through the high-current path.

Meanwhile, the compensation transformer included in the second compensation unit 140D-2 may generate, in the secondary side, the compensation current Iᵢₙⱼ₂ to be injected into the high-current path, based on the second compensation signal S1-2 output from the IC unit 500′. The current (i.e., a secondary side current) Iᵢₙⱼ₂ obtained through conversion by the compensation transformer may be injected into or drawn out of the high-current path through the compensation capacitor unit, as a compensation current.

In an embodiment, the first compensation unit 140D-1 may be arranged in the front of the sensing unit 120D, and the second compensation unit 140D-2 may be arranged in the rear of the sensing unit 120D. For example, the first compensation unit 140D-1 may perform voltage compensation and the second compensation unit 140D-2 may perform current compensation, at the same time. According to this embodiment, it is possible to simultaneously compensate for a CM voltage and current and thus effectively reduce noise.

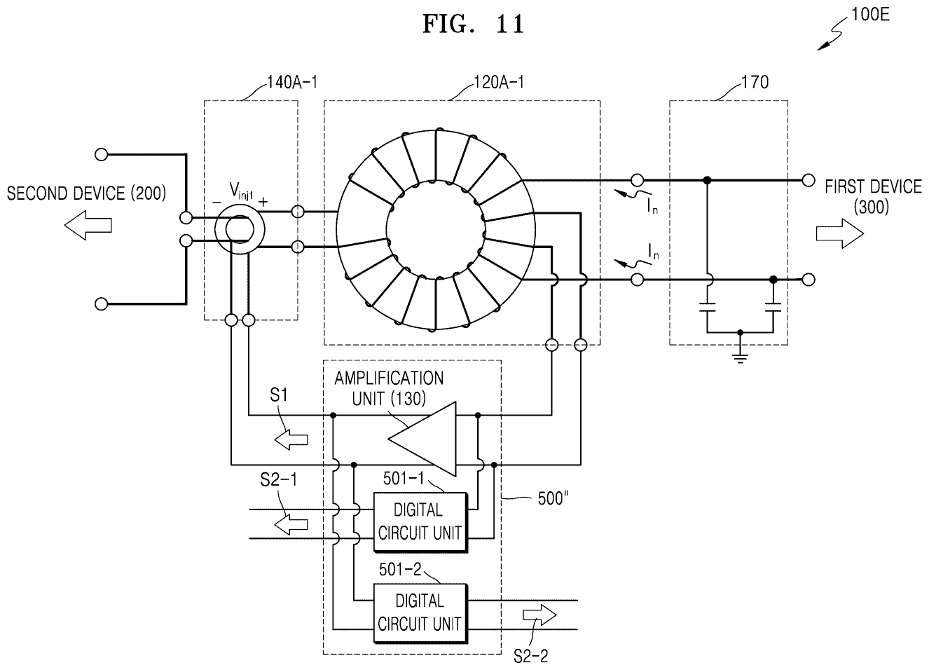

FIG. 11 illustrates a more detailed example of the embodiment illustrated in FIG. 1, and schematically illustrates an active compensation device 100E according to an embodiment of the present disclosure.

The configuration of the active compensation device 100E corresponds to that of the active compensation device 100A-1 illustrated in FIG. 8 except for an IC unit 500″, and thus, descriptions thereof will be omitted.

In the active compensation device 100E according to an embodiment, the IC unit 500″ may include the amplification unit 130, a first digital circuit unit 501-1, and a second digital circuit unit 501-2.

Like the above-described examples of the digital circuit units 501, the first digital circuit unit 501-1 may output first digital noise data S2-1 based on the same input signal as the input signal of the amplification unit 130 (i.e., the input signal of the IC unit 500″). The second digital circuit unit 501-2 may output second digital noise data S2-2 based on an output signal of the amplification unit 130.

According to the present embodiment, in the IC unit 500″, the output terminal of the amplification unit 130 may be connected to an input terminal of the second digital circuit unit 501-2.

According to the present embodiment, the first digital circuit unit 501-1 and the second digital circuit unit 501-2 may convert analog signals from the input terminal and the output terminal of the amplification unit 130 into digital data, respectively. That is, the IC unit 500″ may sense both analog signals before and after amplification and output pieces of digital data S2-1 and S2-2 corresponding to the analog signals, respectively. According to the present embodiment, not only output noise data (e.g., the first noise data S2-1) of the sensing unit 120, but also output noise data (e.g., the second noise data S2-2) of the amplification unit 130 may be monitored. For example, the first noise data S2-1 and the second noise data S2-2 may be used to determine whether the analog amplification unit 130 is operating normally.

According to various embodiments of the present disclosure described above, it is possible to collect noise data while compensating for a noise signal by using the active compensation device 100, 100A, 100A-1, 100B, 100C, 100D, or 100E.

Meanwhile, conductive emission noise includes common-mode (CM) noise and differential-mode (DM) noise. The CM noise is noise generated when a power conversion device converts direct current into alternating current and converts alternating current into direct current, and is returned through the ground GND. Therefore, in the case of the CM noise, noises flow in the same direction on each of at least two power lines. The DM noise is noise generated by the power conversion device, similar to the CM noise, but is returned from the live power line to the neutral power line rather than to the ground. Therefore, in the case of the DM noise, the noises flow in opposite directions on each of at least two power lines.

In general, in order to reduce the two modes of noise simultaneously, a CM choke coil for canceling the CM noise is required and separate wire installation or additional filters for reducing the DM noise are further required between the power source and the load.

However, adding separate components or wires to noise compensation devices (EMI filters) in order to control the two modes of noise may cause design restrictions or increase unit cost in low-power home appliances, and make product miniaturization and integration difficult. In some cases, the filters and the power lines may require a common ground, making the filters and the power lines unusable in two-prong home appliances.

Meanwhile, the noise compensation devices may be classified into passive compensation devices and active noise compensation devices depending on the types of components included therein. The passive compensation device refers to a filter that includes at least one selected from a group of passive elements including resistors, inductors, and capacitors, and the active compensation device refers to a filter that further includes active elements.

However, in active circuits or active systems such as the active compensation devices, oscillations in which unidentified resonant signals are detected in unwanted frequency bands may occur. Such oscillations may cause the active compensation devices to become unstable and, in severe cases, may damage the circuits. That is, because the active compensation devices may normally reduce noise without generating noise on their own when no oscillations occur, measures to prevent oscillations are necessary.

In order to improve the above-mentioned issues, an active compensation device including an oscillation prevention function to cancel CM noise and DM noise is disclosed.

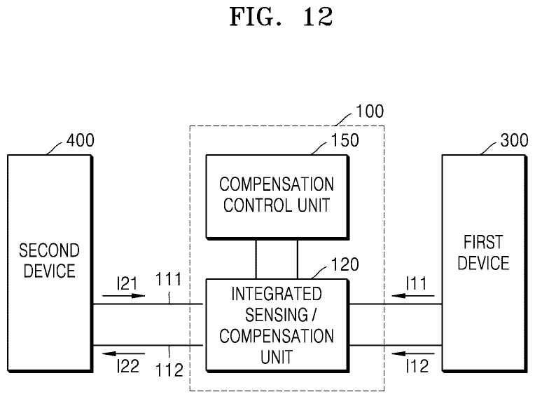

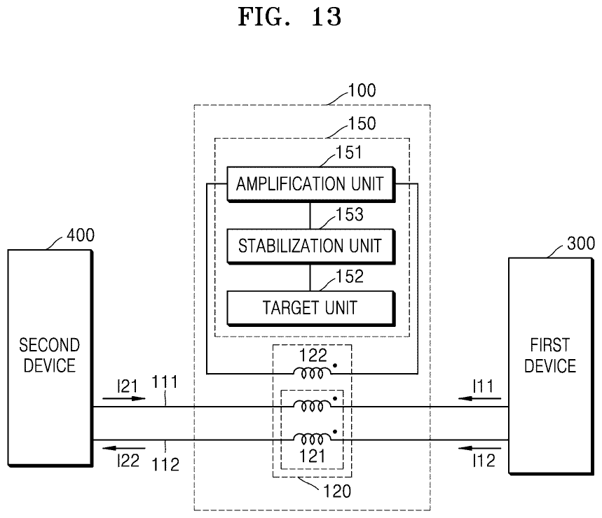

FIG. 12 schematically illustrates a configuration of a voltage compensation system including an active compensation device 100 according to an embodiment of the present disclosure. FIG. 13 illustrates a more detailed example of the active compensation device 100 of FIG. 12.

Referring to FIGS. 12 and 13, the active compensation device 100 according to an embodiment of the present disclosure may actively compensate for first noises I11 and I12 generated and input in a CM and second noises I21 and I22 generated and input in a DM, on each of at least two high-current paths 111 and 112 connected to a first device 300. To this end, the active compensation device 100 according to an embodiment of the present disclosure may include an integrated sensing/compensation unit 120 that senses the first noises I11 and I12 and the second noises I21 and I22 by a voltage difference, and a compensation control unit 150 that is connected to the integrated sensing/compensation unit 120 and generates a compensation voltage based on the sensed first noises I11 and I12 and the sensed second noises I21 and I22 and provides the compensation voltage to the integrated sensing/compensation unit 120.

The two or more high-current paths 111 and 112 may be paths through which power supplied by a second device 400 within the active compensation device 100 is transferred to the first device 300, and may be, for example, power lines. According to an embodiment, each of the two or more high-current paths 111 and 112 may be a live line and a neutral line. For convenience of description, the following description focuses on a configuration in which the system includes two high-current paths 111 and 112.

In the present specification, the second device 400 may be various types of devices for supplying power to the first device 300 in the form of current and/or voltage. For example, the second device 400 may be a device for generating and supplying power or may be a device (e.g., a power source) for supplying power generated by another device. Of course, the second device 400 may also be a device for supplying stored energy. However, this is an example and the concept of the present disclosure is not limited thereto.

In the present specification, the first device 300 may be various types of devices that use power supplied by the second device 400 described above. For example, the first device 300 may be a load driven by using power supplied by the second device 400. In addition, the first device 300 may be a load (e.g., a home appliance, a television (TV), a computer, a monitor, a printer, etc.) that stores energy by using power supplied by the second device 200 and is driven by using the stored energy. However, this is an example and the concept of the present disclosure is not limited thereto.

In addition, each of the two or more high-current paths 111 and 112 may be a path which is made of a conductive material and through which conductive noise generated in the process of converting the power input from the first device 300 into direct current or alternating current is transferred. The conductive noise includes the first noises I11 and I12, which are CM noise, and the second noises I21 and I22, which are DM noise.

The first noises I11 and I12 are generated in the second device 400, flows along the two or more high-current paths 111 and 112, and are returned through the ground. Therefore, in the case of the first noises I11 and I12, when comparing the two high-current paths 111 and 112, the noises flow in the same direction. Meanwhile, the second noises I21 and I22 are generated in the second device 400, pass through the first device 300 along the first high-current path 111, which is the live line, and are returned through the second high-current path 112, which is the neutral line. Therefore, in the case of the second noises I21 and I22, when comparing the two high-current paths 111 and 112, the noises flow in opposite directions. Both the first noises I11 and I12 and the second noises I21 and I22 may be currents having a frequency of a specific band. Here, the frequency bands of the first noises I11 and I12 and the second noises I21 and I22 may be bands having a range of, for example, 150 kHz to 30 MHz.

Meanwhile, the integrated sensing/compensation unit 120 is electrically connected to the high-current paths 111 and 112 and senses a first noise voltage and a second noise voltage together on the two or more high-current paths 111 and 112 and generates a sensing signal corresponding thereto. In other words, the integrated sensing/compensation unit 120 may refer to a means for sensing CM noise and DM noise on the high-current paths 111 and 112.

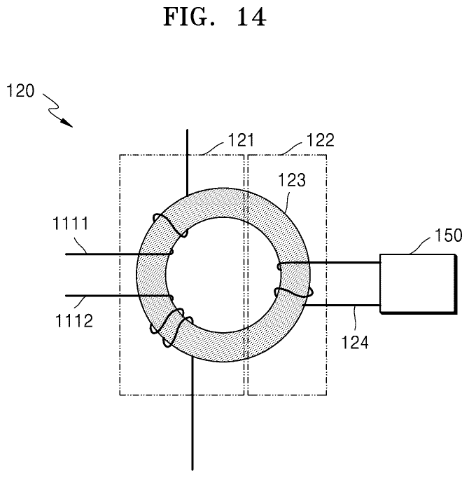

The integrated sensing/compensation unit 120 may be a means for sensing noise voltages on the high-current paths 111 and 112, while being insulated from the high-current paths 111 and 112. In an embodiment, the integrated sensing/compensation unit 120 may simultaneously sense the first noise voltage and the second noise voltage at terminals of a sensing/compensation winding 124, which will be described below with reference to FIG. 14. In other words, the integrated sensing/compensation unit 120 generates the sensing signal at one end including the sensing/compensation winding 124. In this case, the sensing signal may include both information about the first noise voltage and information about the second noise voltage. In an optional embodiment, the integrated sensing/compensation unit 120 may separately sense the first noise voltage and the second noise voltage. In this case, the sensing signal may include a first sensing signal corresponding to the first noise voltage and a second sensing signal corresponding to the second noise voltage.

The compensation control unit 150 may be electrically connected to the integrated sensing/compensation unit 120 and may receive the sensing signal corresponding to the sensed first noise voltage and the sensed second noise voltage from the integrated sensing/compensation unit 120, generate a compensation signal (e.g., a compensation voltage or a compensation current) corresponding to the first noise voltage and the second noise voltage, and transfer the compensation signal to the integrated sensing/compensation unit 120 through the sensing/compensation winding 124. Hereinafter, a case where the compensation signal is the compensation voltage will be described.

In the active compensation device 100 of FIG. 12 according to an embodiment, noise sensing and noise compensation are performed at the same location. That is, in the active compensation device 100 of FIG. 12 according to an embodiment, an induced voltage corresponding to the sensing signal is formed at a terminal node of the sensing/compensation winding 124, and a corresponding compensation voltage or compensation current may be formed at the terminal node of the sensing/compensation winding 124.

The compensation control unit 150 is connected only to the integrated sensing/compensation unit 120 and is not connected to the two or more high-current paths 111 and 112. That is, the compensation control unit 150 is not a component that transfers the compensation voltage to the high-current paths 111 and 112, and thus, the active compensation device 100 according to an embodiment of the present disclosure has an effect of filtering out noise without requiring an additional component to be added to the power line.

An effective impedance of the integrated sensing/compensation unit 120 increases due to the compensation voltage transferred by the compensation control unit 150, and the flow of the first noises I11 and I12 and the second noises I21 and I22 flowing through the high-current paths 111 and 112 is suppressed by the increased effective impedance. Consequently, both the first noises I11 and I12 and the second noises I21 and I22 on the high-current paths 111 and 112 are compensated for.

The compensation control unit 150 may be a component that provides a negative impedance. The compensation control unit 150 may include a negative impedance converter (NIC). In an embodiment, the compensation control unit 150 may include an NIC to generate a compensation voltage through the negative impedance based on the sensed noise and provide the compensation voltage to the integrated sensing/compensation unit 120. In the case of the active compensation device including the NIC, there is an advantage in that the integrated sensing/compensation unit 120 and the compensation control unit 150 may be present in the same location, and thus, there is no need for a separate device for compensation. In addition, because the sensing/compensation paths for the CM noise and the DM noise coincide with each other, there is an advantage in that the CM noise and the DM noise may be simultaneously reduced.

Meanwhile, the compensation control unit 150 of the active compensation device may further include a stabilization unit 153 that prevents oscillation that may occur during a feedback operation of the compensation control unit 150. In detail, the compensation control unit 150 may include an amplification unit 151 that receives the sensing signal corresponding to the first noise voltage and the second noise voltage, which are sensed by the integrated sensing/compensation unit 120, amplifies the sensing signal, and generates an amplified signal, a target unit 152 that generates the compensation voltage based on the amplified signal, and the stabilization unit 153 that is connected to the target unit 152 and prevents oscillation caused by the sensed noises.

In an embodiment, the magnitude of the impedance of the target unit 152 and the stabilization unit 153 is greater than the magnitude of the total input impedance viewed from the compensation control unit 150 toward the integrated sensing/compensation unit 120. Here, the total input impedance includes not only an impedance component of the integrated sensing/compensation unit 120, but also a parasitic capacitance included in the high-current paths 111 and 112, a capacitance of the second device 400, and a capacitance of the first device 300. Through these features, the active compensation device 100 according to an embodiment of the present disclosure has an effect of preventing oscillation caused by noise and performing a stable voltage compensation operation.

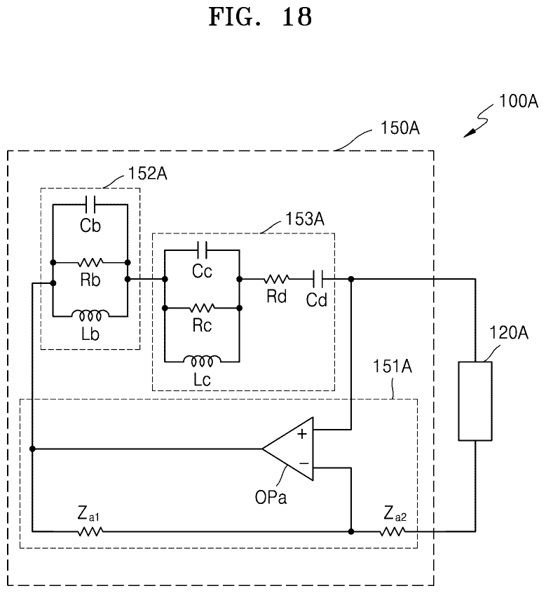

Referring again to FIG. 13, the amplification unit 151, the target unit 152, and the stabilization unit 153 may be implemented by various means. In an embodiment, the amplification unit 151 may include at least one amplifier, for example, an operational amplifier (OP-amp). The target unit 152 may include at least one inductor and at least one capacitor. In addition, the stabilization unit 153 may include at least one capacitor and at least one inductor, or may include at least one amplifier and at least one capacitor. However, the above-described implementation method of the amplification unit 151, the target unit 152, and the stabilization unit 153 is an example and the concept of the present disclosure is not limited thereto. A specific configuration of the compensation control unit 150 will be described in detail below with reference to FIG. 18.

The active compensation device 100 configured as described above may effectively compensate for the CM noise and the DM noise by sensing the voltages of the CM noise and the DM noise on the two or more high-current paths 111 and 112 and generating the compensation voltage corresponding thereto to increase the effective impedance on the high-current paths 111 and 112. In addition, the active compensation device 100 configured as described above achieves a stable voltage compensation operation by minimizing oscillation caused by noise.

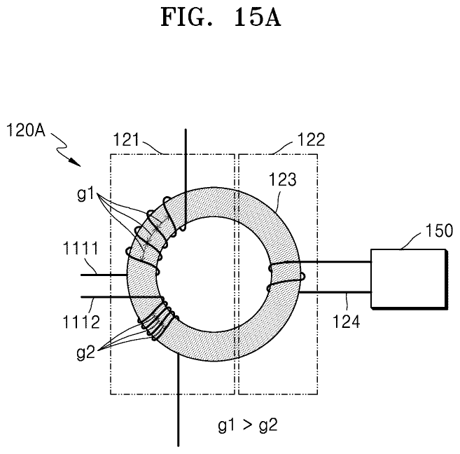

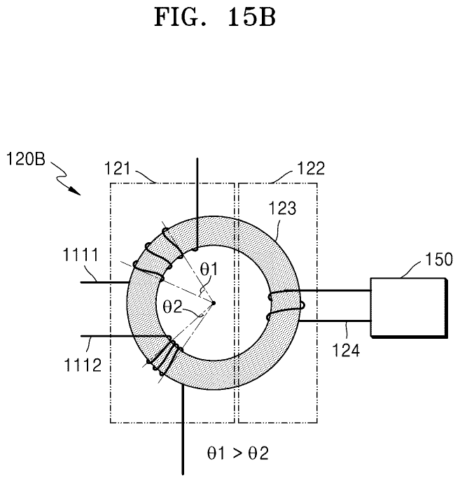

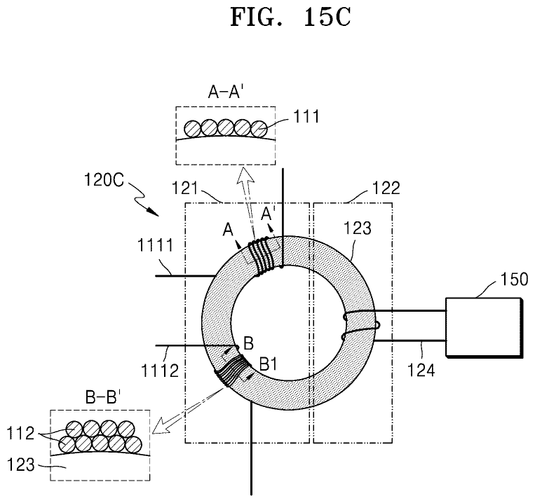

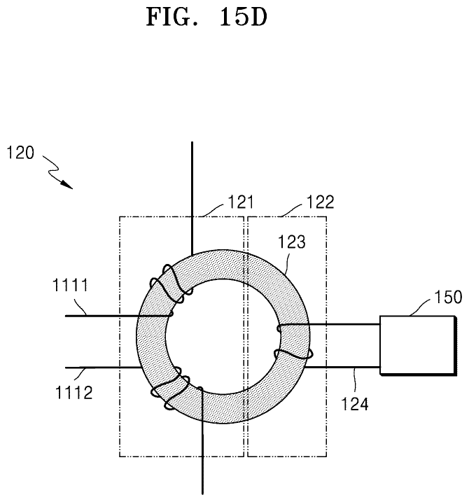

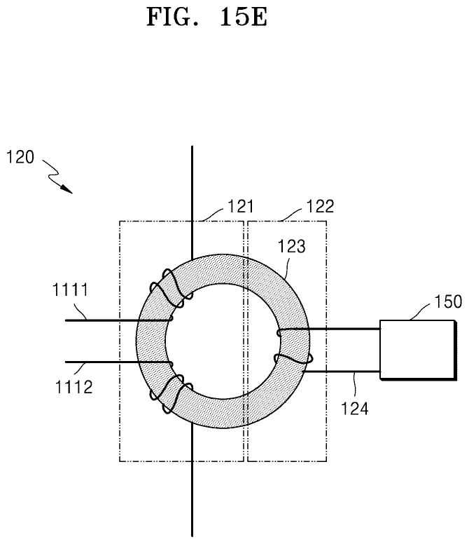

FIG. 14 illustrates a more detailed example of a choke coil included in the integrated sensing/compensation unit 120. FIGS. 15A to 15E illustrate other more detailed examples of a choke coil.

According to an embodiment illustrated in FIG. 14, the integrated sensing/compensation unit 120 may include at least one choke coil. In this case, the choke coil may include a conductor including a through hole, and conductive windings passing through the through hole or passing through the through hole and then wound around the conductor at least once.

The conductor including the through hole may be a core 123 in the form of a closed loop, but the present disclosure is not limited thereto, and the conductor may be implemented so that a portion of the loop may be opened or closed in the form of a clamp. Any conductor may be used as long as the conductor includes a through hole.

The conductive windings may include at least two high-current path windings 1111 and 1112 and a sensing/compensation winding 124. In detail, the at least two high-current path windings 1111 and 1112 are respectively connected to the at least two high-current paths 111 and 112. For example, the high-current path windings 1111 and 1112 may be portions of the high-current paths 111 and 112, or may be directly or indirectly connected to the high-current paths 111 and 112. The high-current path windings 1111 and 1112 may be electrically connected to the high-current paths 111 and 112.

Each of the at least two high-current path windings 1111 and 1112 passes through at least the through hole. For example, each of the high-current path windings 1111 and 1112 may pass through the through hole at least once, or may pass through the through hole multiple times and be then wound around the conductor (e.g., the core 123) at least once.

In an embodiment, each of the high-current path windings 1111 and 1112 may be wound asymmetrically around the conductor (e.g., the core 123). In other words, each of the high-current path windings 1111 and 1112 must have a structure such that coupling coefficients are different from each other.

FIG. 14 illustrates an example in which the number of turns of the high-current path winding 1111 is different from the number of turns of the high-current path winding 1112. Referring to FIG. 14, it is illustrated that the first high-current path winding 1111 is wound once around the core 123, which is the conductor, and the second high-current path winding 1112 is wound twice around the core 123, which is the conductor, but the concept of the present disclosure is not limited thereto.

FIGS. 15A to 15C further illustrate examples in which the high-current path windings 1111 and 1112 are wound asymmetrically around the conductor (e.g., the core 123).

FIG. 15A illustrates an example in which the degree of winding density of the high-current path winding 1111 is different from the degree of winding density of the high-current path winding 1112. Referring to FIG. 15A, it is illustrated that the second high-current path winding 1112 is wound more densely around the core 123, which is the conductor, than the first high-current path winding 1111. That is, a gap g1 between the first high-current path windings 1111 wound around the core 123 is greater than a gap g2 between the second high-current path windings 1112 wound around the core 123. (g1>g2)

FIG. 15B illustrates an example in which the magnitude of the winding angle of the high-current path winding 1111 is different from the magnitude of the winding angle of the high-current path winding 1112. Referring to FIG. 15B, it is illustrated that the magnitude of the winding angle of the first high-current path winding 1111 is greater than the magnitude of the winding angle of the second high-current path winding 1112. That is, based on one surface of the core 123, an angle θ1 of straight lines (rays) connecting from the center of the core 123 to the outermost first high-current path windings 1111 that are the starting and ending first high-current path windings 1111 wound around the core 123 is greater than an angle θ2 of straight lines (rays) connecting from the center of the core 123 to the outermost second high-current path windings 1112 that are the starting and ending second high-current path windings 1112 wound around the core 123. (θ1>θ2)

FIG. 15C illustrates an example in which overlap winding of the high-current path windings 1111 and 1112 is different. Referring to FIG. 15C, it is illustrated that the first high-current path winding 1111 is wound around the core 123, which is the conductor, in only one layer without overlapping, and the second high-current path winding 1112 is wound around the core 123, which is the conductor, in two layers, and it is illustrated that the first high-current path winding 1111 is wound with zero overlapping turns and the second high-current path winding 1112 is wound with one overlapping turn.

Because the descriptions provided with reference to FIGS. 15A to 15C are examples, the concept of the present disclosure is not limited thereto, and any configuration in which each of the high-current path windings 1111 and 1112 is wound asymmetrically around the conductor may be adopted.

As such, because each of the high-current path windings 1111 and 1112 is wound asymmetrically around the conductor (e.g., the core 123), the active compensation device may sense both the CM noise and the DM noise, and thus, the active compensation device may compensate for noise including both the CM noise and the DM noise.

Meanwhile, in an optional embodiment, the active compensation device may sense and compensate for only one of the CM noise and the DM noise. For example, FIG. 15D illustrates an example in which the number of turns of the high-current path winding 1111 is equal to the number of turns of the high-current path winding 1112, but the winding direction of the high-current path winding 1111 is different from the winding direction of the high-current path winding 1112. That is, both the first high-current path winding 1111 and the second high-current path winding 1112 are wound twice around the core 123, but the first high-current path winding 1111 may be wound clockwise or counterclockwise with respect to the core 123, or the second high-current path winding 1112 may be wound counterclockwise or clockwise with respect to the core 123. In this case, the choke coil may sense only the DM noise, and the active compensator compensates only for the DM noise.

As another example, FIG. 15E illustrates an example in which the winding direction and the number of turns of the high-current path winding 1111 are the same as the winding direction and the number of turns of the high-current path winding 1112, and thus, the high-current path windings 1111 and 1112 are completely symmetrically wound around the conductor (e.g., the core 123). That is, both the first high-current path winding 1111 and the second high-current path winding 1112 may be wound twice around the core 123, and both the first high-current path winding 1111 and the second high-current path winding 1112 may be wound in the same clockwise or counterclockwise direction with respect to the core 123. In this case, the choke coil may sense only the CM noise, and the active compensation device may compensate only for the CM noise.

Meanwhile, although not illustrated in FIGS. 14 and 15A to 15E, one ends and the other ends of the at least two high-current path windings 1111 and 1112 are directly or indirectly connected to the first device 300 and the second device 400, respectively.

Referring again to FIG. 14, in the same manner as the high-current path windings 1111 and 1112, the sensing/compensation winding 124 also passes through at least the through hole. For example, the sensing/compensation winding 124 may pass through the through hole at least once, or may pass through the through hole multiple times and be then wound around the conductor at least once. Meanwhile, one end and the other end of the sensing/compensation winding 124 are each connected to the compensation control unit 150.

The side where the high-current path windings 1111 and 1112 of the choke coil of the integrated sensing/compensation unit 120 are arranged may be referred to as a primary side 121 of the choke coil, and the side where the sensing/compensation winding 124 is arranged may be referred to as a secondary side 122 of the choke coil. The choke coil may generate an induced voltage in the secondary side 122, based on a magnetic field induced by noises I11, I12, I21, and I22 in the primary side 121 arranged on the high-current path windings 1111 and 1112. That is, the induced voltage induced in the secondary side 122 of the choke coil may be a voltage corresponding to the current into which the noises I11, I12, I21, and I22 are converted at a certain ratio.

In the choke coil, when a turns ratio of the primary side 121 to the secondary side 122 is 1:Nₛₑₙ and a self-inductance of the primary side 121 of the choke coil is Lₛₑₙ, the secondary side 122 may have a self-inductance of Nₛₑₙ²Lₛₑₙ.

In this case, when a voltage induced at both ends of the primary side of the choke coil due to the first noises I11 and I12 is V_{cm}, a voltage V_{cm,sen} induced in the secondary side is Nₛₑₙ times V_{cm}. Similarly, when a voltage induced at both ends of the primary side of the choke coil due to the second noises I21 and I22 is V_{dm}, a voltage V_{dm,sen} induced in the secondary side is Nₛₑₙ times V_{dm}.

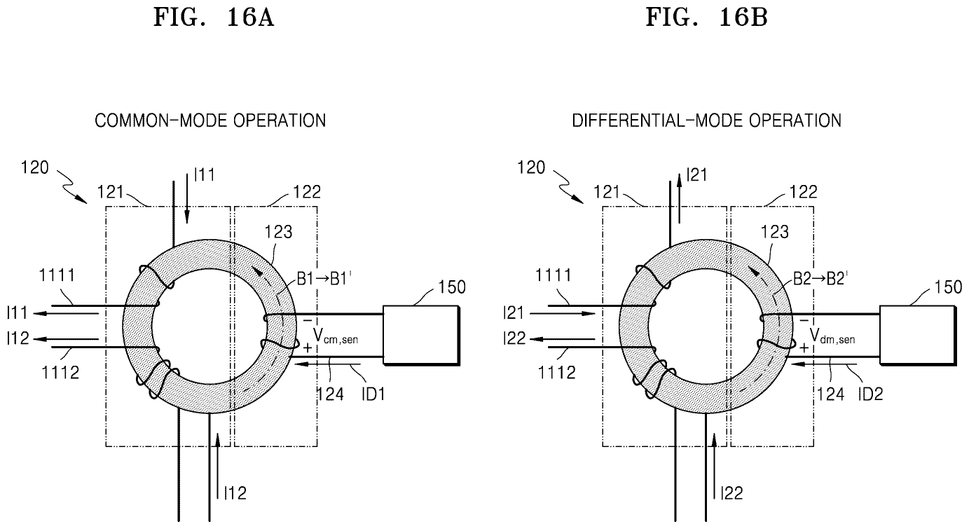

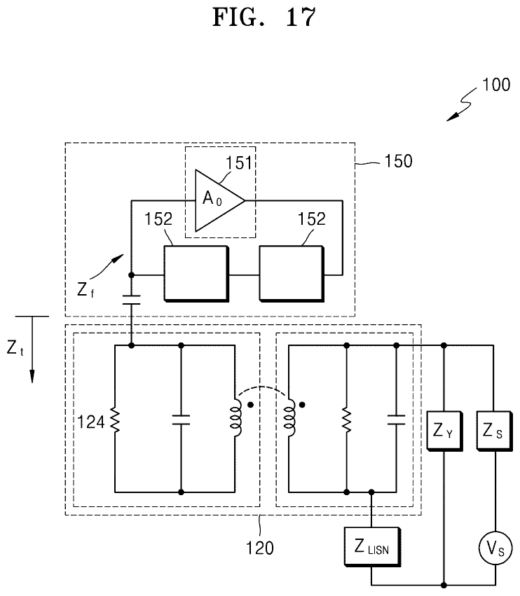

FIGS. 16A and 16B illustrates a method by which the active compensation device 100 compensates for noise, according to an embodiment.

The active compensation device according to an embodiment senses at least one of CM noise and DM noise on at least two high-current paths, and generates an induced voltage corresponding to the sensed noise in the sensing/compensation winding 124. The active compensation device generates a compensation voltage based on the induced voltage and applies the compensation voltage to the sensing/compensation winding 124 so that the choke coil included in the active compensation device is activated to offset noise. Here, the active compensation device generates a compensation voltage or a compensation current corresponding to the impedance of the target unit and the stabilization unit included in the active compensation device.

The case of FIG. 16A illustrates a noise reduction method related to the first noises I11 and I12, which are the CM noise, and the case of FIG. 16B illustrates a noise reduction method related to the second noises I21 and I22, which are the DM noise. In FIGS. 16A and 16B, for convenience of description, the conductor of the choke coil is illustrated in the form of the core 123, and the two high-current path windings 1111 and 1112 are illustrated, wherein the first high-current path winding 1111 is illustrated as being wound once through the through hole of the core 123 and the second high-current path winding 1112 is illustrated as being wound twice through the through hole of the core 123, such that the two high-current path windings 1111 and 1112 are asymmetrically implemented. In addition, the compensation control unit 150 includes a negative impedance converter, but this is an example and the concept of the present disclosure is not limited thereto.

First, referring to FIG. 16A, when the first noise I11 is input to the first high-current path winding 1111, a 1-1st magnetic field (B11, not shown) may be induced in the core 123, and when the first noise I12 is input to the second high-current path winding 1112, a 1-2nd magnetic field (B12, not shown) may be induced in the core 123. Here, because the first noises I11 and I12, which are CM noises, are signals or currents that flow in the same direction with respect to each of the high-current path windings 1111 and 1112, magnetic fields are formed in the core 123 in the same direction. Therefore, the 1-1st magnetic field B11 and the 1-2nd magnetic field B12 overlap each other (or reinforce each other) to form a first magnetic field B1, which is counterclockwise in FIG. 16A. Meanwhile, the first induced voltage V_{cm,sen} corresponding to the first magnetic field B1 is induced in the sensing/compensation winding 124 of the secondary side 122 insulated from the high-current path windings 1111 and 1112 by the formed first magnetic field B1. Meanwhile, the compensation control unit 150 connected to the sensing/compensation winding 124 of the secondary side 122 generates a first compensation current ID1 corresponding to a first compensation voltage having a first flux that may overlap (reinforce) the first magnetic field B1 based on the first induced voltage V_{cm,sen} by the negative impedance converter. The generated first compensation current ID1 flows into the choke coil and makes the first magnetic field B1 stronger by reinforcing the first flux. Therefore, the effective impedance increases due to the reinforced first magnetic field B1′, and the choke coil becomes active. As a result, the flow of the first noises I11 and I12 flowing through the first high-current path 111 and the second high-current path 112 is suppressed by inductance boosting, and thus. noise filtering is enabled by voltage sensing and voltage compensation.

Next, referring to FIG. 16B, when the second noise I21 is input to the first high-current path winding 1111, a 2-1st magnetic field (B21, not shown) may be induced in the core 123, and when the second noise 122 is input to the second high-current path winding 1112, a 2-2nd magnetic field (B22, not shown) may be induced in the core 123. Here, because the second noises I21 and I22, which are DM noises, are signals or currents that flow in different directions with respect to each of the high-current path windings 1111 and 1112, magnetic fields are formed in the core 123 in opposite directions. Accordingly, the 2-1st magnetic field B21 and the 2-2nd magnetic field B22 offset each other, but in an embodiment, because the first high-current path winding 1111 and the second high-current path winding 1112 are wound asymmetrically around the core 123, a difference exists between the 2-1st magnetic field B21 and the 2-2nd magnetic field B22 due to different coupling coefficients, and the second magnetic field B2 is formed by the difference therebetween. Meanwhile, the second induced voltage V_{dm,sen} corresponding to the second magnetic field B2 is induced in the sensing/compensation winding 124 of the secondary side 122 insulated from the high-current path windings 1111 and 1112 by the formed second magnetic field B1. Meanwhile, the compensation control unit 150 connected to the sensing/compensation winding 124 of the secondary side 122 generates a second compensation current ID2 corresponding to a second compensation voltage having a second flux that may overlap (reinforce) the second magnetic field B2 based on the second induced voltage by the negative impedance converter. The generated second compensation current ID2 flows into the choke coil and makes the second magnetic field B2 stronger by reinforcing the second flux. Therefore, the effective impedance increases due to the reinforced second magnetic field B2′, and the choke coil is activated. As a result, the flow of second noises I21 and I22 flowing through the first high-current path 111 and the second high-current path 112 is also suppressed together with the flow of the first noises I11 and I12 by inductance boosting, and thus, CM and DM noise filtering is enabled by voltage sensing and voltage compensation.

Meanwhile, in FIGS. 16A and 16B, for convenience of description, noise reduction methods related to CM noise and DM noise are described separately, but because the active compensation device 100 according to an embodiment of the present disclosure may compensate for the CM noise and the DM noise simultaneously, the operations described with reference to FIGS. 16A and 16B may occur simultaneously.

FIG. 17 illustrates an equivalent circuit of the voltage compensation system of FIG. 12, according to an embodiment of the present disclosure.

Because the voltage compensation system of FIG. 17 is an equivalent circuit of FIG. 12, the voltage compensation system of FIG. 17 includes an active compensation device 100 that actively compensates for the CM noise and the DM noise of each of the two or more high-current paths 111 and 112. Hereinafter, descriptions redundant with those provided with reference to FIGS. 12 to 16A and 16B are omitted, and the operating method of the active compensation device 100 is mainly described.

Referring to FIG. 17, with regard to the CM noise, the first induced voltage induced by the first noises I11 and I12 sensed in the choke coil is input to the compensation control unit 150 as a first input signal of the compensation control unit 150 connected to the sensing/compensation winding 124, as described with reference to FIG. 16A. The compensation control unit 150 includes the negative impedance converter to generate the first compensation voltage corresponding to the first input signal.

In detail, the first input signal is input to the amplification unit 151, and the amplification unit 151 amplifies the first input signal according to a gain A0 to generate a first amplified signal. The amplification unit 151 may refer to controlling the magnitude and/or phase of an object to be amplified, and FIG. 17 illustrates that the amplification unit 151 includes one OP-amp, but the present disclosure is not limited thereto, and the amplification unit 151 may include a plurality of passive elements such as resistors and capacitors, in addition to the OP-amp. In addition, in an optional embodiment, the amplification unit 151 may include two or more OP-amps and may include a bipolar junction transistor (BJT), and a means for amplification may be used without limitation. The generated first amplified signal may be an amplified voltage, and the first amplified signal is input to the target unit 152 and the stabilization unit 153.

Meanwhile, when the first amplified signal is input to the target unit 152 and the stabilization unit 153, the first compensation voltage corresponding to the negative impedance is generated based on the input first amplified signal. In an embodiment, the magnitude Zf of the impedance of the target unit 152 and the stabilization unit 153 is designed to be greater than the magnitude Zₜ of the total input impedance viewed from the compensation control unit 150 toward the integrated sensing/compensation unit 120. Accordingly, the first compensation current corresponding to the generated first compensation voltage flows along the sensing/compensation winding 124 toward the integrated sensing/compensation unit 120 having a small impedance, the effective impedance of the choke coil increases as the flux increases due to the first compensation current flowing into the choke coil, and the first noises I11 I12, which are CM noise, are suppressed.

Similarly, with regard to the DM noise, the second induced voltage induced by the second noises I21 and I22 sensed in the choke coil is input to the compensation control unit 150 as a second input signal of the compensation control unit 150 connected to the sensing/compensation winding 124, as described with reference to FIG. 16B. The compensation control unit 150 includes the negative impedance converter and generates the second compensation voltage corresponding to the second input signal. In detail, the second input signal is input to the amplification unit 151, and the amplification unit 151 amplifies the second input signal according to a gain A0 to generate a second amplified signal. The generated second amplified signal may be an amplified voltage, and the second amplified signal is input to the target unit 152 and the stabilization unit 153. The second amplified signal is input to the target unit 152 and the stabilization unit 153, and the second compensation voltage corresponding to the negative impedance is generated based on the input second amplified signal. As described above, in an embodiment, the magnitude Zr of the impedance of the target unit 152 and the stabilization unit 153 is designed to be greater than the magnitude of the total impedance viewed from the compensation control unit 150 toward the integrated sensing/compensation unit 120. Accordingly, the second compensation current corresponding to the second compensation voltage flows along the sensing/compensation winding 124 toward the integrated sensing/compensation unit 120 having a small impedance, the effective impedance of the choke coil increases as the flux increases due to the second compensation current flowing into the choke coil, and the second noises I21 I22, which are the DM, are reduced.

Here, the total impedance is the input impedance viewed toward the sensing/compensation winding 124 from the compensation control unit 150, which reflects the influence of parasitic capacitances included in the high-current paths 111 and 112 and denoted by Z_{Y} and Z_{S}, a capacitance of the second device 400 denoted by Z_{LISN}, and a capacitance of the first device 300 which is Vₛ not shown, in addition to the impedance components of the choke coil and the sensing/compensation winding 124 included in the integrated sensing/compensation unit 120.

Meanwhile, the target unit 152 may be connected to an output unit of the amplification unit 151 and may include at least one inductor and capacitor as essential components. Here, the inductor may serve to make negative impedance together with the amplification unit 151, and the capacitor may be provided for DC coupling to ensure the stability of the circuit. The target unit 152 may further include a resistor in addition to the inductor and the capacitor, and may be variously modified depending on the design.

Meanwhile, the stabilization unit 153 may be implemented in various embodiments.

In an embodiment, the stabilization unit 153 may be connected to the target unit 152 and may include at least one capacitor and at least one inductor. The stabilization unit 153 may prevent oscillation of the active compensation device by making, together with the target unit 152, the magnitude of the impedance of the target unit 152 and the stabilization unit 153 greater than the magnitude of the total input impedance viewed from the compensation control unit 150 toward the integrated sensing/compensation unit 120.

In another embodiment, the stabilization unit 153 may be connected to an output terminal or an input terminal of the amplification unit 151 and may include at least one band-pass filter. The stabilization unit 153 may prevent oscillation of the active compensation device by controlling the output of the amplification unit 151 in a frequency band where there is a risk of oscillation. In detail, the stabilization unit 153 may include at least one selected from the group consisting of a low-pass filter and a high-pass filter, which makes the amplification unit 151 have a low output in a oscillation risk frequency band. In addition, the stabilization unit 153 may prevent oscillation of the active compensation device by making the magnitude of the impedance of the target unit 152 and the stabilization unit 153 in the oscillation risk frequency band greater than the magnitude of the total input impedance viewed from the compensation control unit 150 toward the integrated sensing/compensation unit 120. For example, the oscillation risk frequency band may be a band ranging from more than 1 kHz to less than 1 GHz.

In another embodiment, the stabilization unit 153 may be connected to the output terminal of the amplification unit 151 and may include at least one phase shifter. The stabilization unit 153 may prevent oscillation of the active compensation device by controlling the phase of the output of the amplification unit 151 in the oscillation risk frequency band.

Hereinafter, the effects of the present disclosure are clearly described by taking an example of a case where oscillation occurs. For the convenience of description, only the case of CM noise is taken as an example. In case that the first input signal is input to the amplification unit 151, the amplification unit 151 amplifies the first input signal according to the gain A0 to generate the first amplified signal, and the generated first amplified signal is input to the target unit 152 and the stabilization unit 153, when the magnitude of the impedance of the target unit 152 and the stabilization unit 153 is less than the magnitude of the total impedance viewed from the compensation control unit 150 toward the integrated sensing/compensation unit 120, the first compensation current generated through the target unit 152 and the stabilization unit 153 is fed back to the input of the amplification unit 151. Accordingly, the amplification unit 151 continues to amplify the input being fed back, and thus, the compensation control unit 150 becomes like an oscillator and an oscillation phenomenon in which an unwanted peak signal is generated occurs. This applies similarly to DM noise. However, according to an embodiment of the present disclosure, the stabilization unit 153 is provided to design the magnitude of the impedance of the target unit 152 and the stabilization unit 153 to be greater than the magnitude of the total impedance viewed from the compensation control unit 150 toward the integrated sensing/compensation unit 120, thereby preventing oscillation and performing a stable current compensation operation.

FIG. 18 illustrates a detailed example of a circuit of an active compensation device 100A according to an embodiment of the present disclosure.

FIG. 18 is a circuit diagram of the active compensation device 100A according to an embodiment. Descriptions redundant with those provided above with reference to FIGS. 12 to 17, including actively compensating for CM noise and DM noise of each of the two or more high-current paths 111 and 112, are omitted, and the configuration of the circuit diagram is mainly described.

Referring to FIG. 18, the active compensation device 100A may include an integrated sensing/compensation unit 120A and a compensation control unit 150A connected thereto, and the compensation control unit 150A may include an amplification unit 151A, a target unit 152A, and a stabilization unit 153A.

The amplification unit 151A may include one amplifier OPa having a certain gain. An output terminal of the amplifier OPa may be connected to the target unit 152A and a first on-resistor Zₐ₁. In addition, a positive input terminal of the amplifier OPa may be connected to the stabilization unit 153A and a sensing/compensation winding (not shown), and a negative input terminal of the amplifier OPa may be connected to the first on-resistor Zₐ₁ and a second on-resistor Zₐ₂. Although each of the on-resistors is illustrated as including only a resistor, each of the on-resistors may be a combination of one or more resistors, capacitors, and inductors.

The target unit 152A may include a resistor Rb, a capacitor Cb, and an inductor Lb, which are connected in parallel with each other, and the target unit 152A may be connected to the stabilization unit 152A. The stabilization unit 152A may include a resistor Rc, a capacitor Cc, and an inductor Lc, which are connected in parallel with each other, and may further include a resistor Rd and a capacitor Cd connected in series therewith. The target unit 152A and the stabilization unit 153A may be variously modified, and any modification is possible as long as the magnitude of the impedance of the target unit 152A and the stabilization unit 153A may be configured to be greater than the magnitude of the total impedance viewed from the compensation control unit 150A toward the integrated sensing/compensation unit 120A.

The operation of FIG. 18 is described. An input signal from the integrated sensing/compensation unit 120A is input to the compensation control unit 150A, the input signal is amplified through the amplification unit according to the gain of the amplifier OPa included in the amplification unit 151A, and a voltage of the amplified input signal is applied to the target unit 152A and the stabilization unit 153A and is converted into an amplified voltage according to the impedance of the target unit 152A and the stabilization unit 153A. As described with reference to FIG. 17, because the impedance Z_{f} of the target unit 152A and the stabilization unit 153A is greater than the total input impedance Zₜ viewed from the compensation control unit 150A toward the integrated sensing/compensation unit 120A, an amplified current corresponding to the amplified voltage flows toward the integrated sensing/compensation unit 120A, and the choke coil of the integrated sensing/compensation unit 120A is activated.

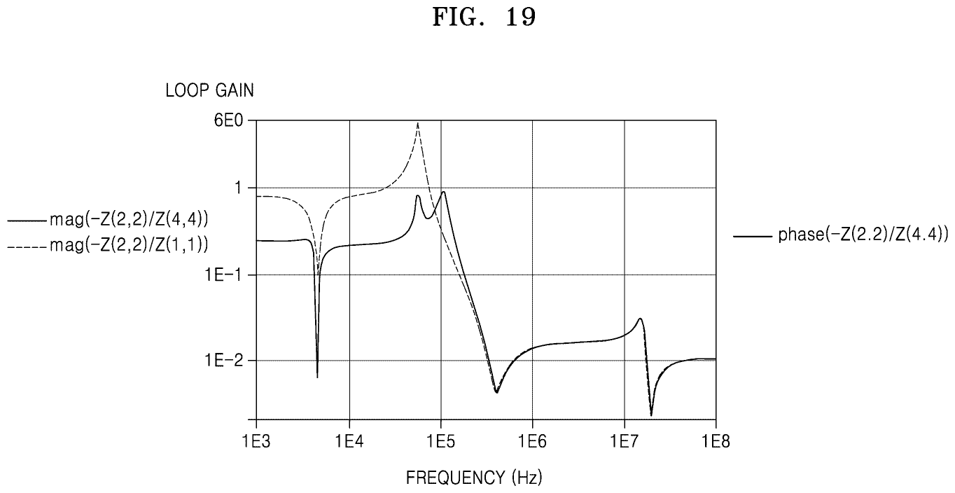

FIG. 19 is a graph comparing oscillation stability of the circuit illustrated in FIG. 18.

Referring to FIG. 19, a dashed line is a loop gain of the circuit of FIG. 18, from which the stabilization unit 153A is excluded, with respect to the frequency, and a solid line is a loop gain of the circuit of FIG. 18, in which the stabilization unit 153A is included, with respect to the frequency. That is, as a result of comparing the performance of the circuit of FIG. 18, in which the stabilization unit 153A is included, with the performance of the circuit of FIG. 18, from which the stabilization unit 153A is excluded, it may be confirmed that the loop gain of the circuit of FIG. 18, in which the stabilization unit 153A is included, does not exceed 1 in a certain frequency band, and thus, the oscillation problem is solved.

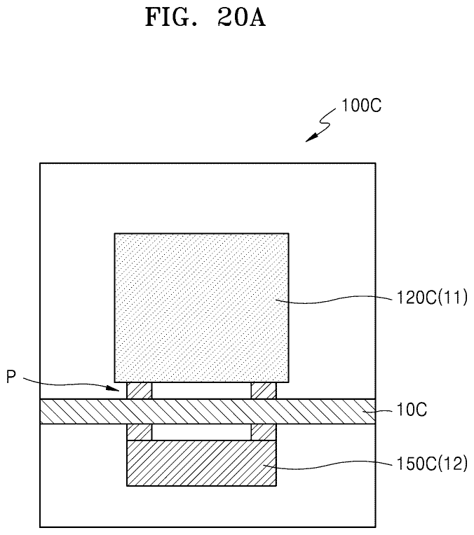

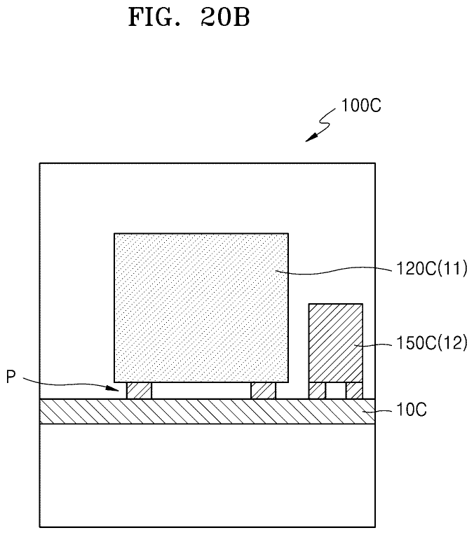

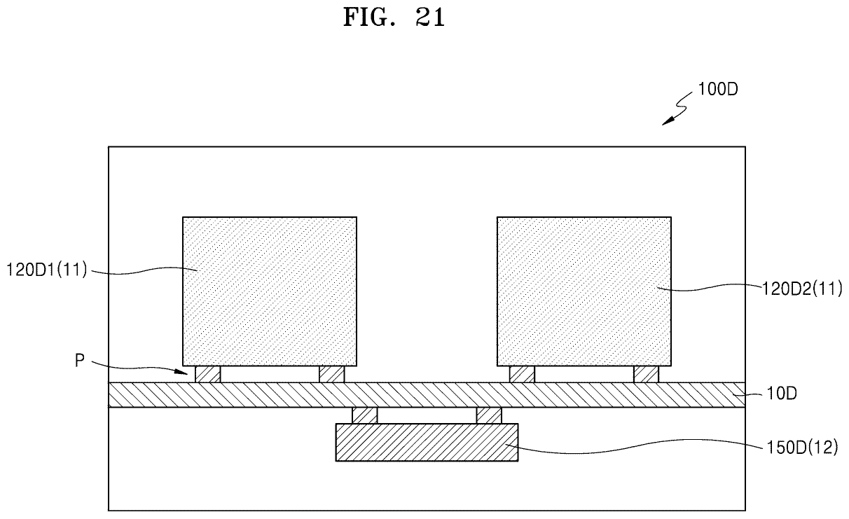

FIGS. 20A and 20B schematically illustrate a structure of an active compensation device 100C according to an embodiment of the present disclosure.

FIGS. 20A and 20B are cross-sectional views illustrating the structure of the active compensation device 100C. Descriptions redundant with those provided above with reference to FIGS. 12 to 19, including actively compensating for CM noise and DM noise of each of the two or more high-current paths 111 and 112, are omitted, and the structure of the active compensation device 100C is mainly described.

Referring to FIGS. 20A and 20B, the active compensation device 100C may include a substrate 10C, and a first element group 11 and a second element group 12 provided in the substrate 10C.

The substrate 10C may include one surface and the other surface. The substrate 10C may include a plurality of conductive pads on the one surface and the other surface and may include a plurality of conductive vias (not shown) electrically connecting the plurality of conductive pads. For example, the substrate 10C may be a printed circuit board (PCB) and may be a double-sided PCB. The substrate 10C is not limited to a rigid PCB or a flexible PCB. The substrate 10C may be variously applied depending on the design.

The first high-current path 111 and the second high-current path 112 pass through the substrate 10C. For example, each of the first high-current path 111 and the second high-current path 112 may be a conductive pattern formed to electrically pass through the substrate 10C from one end to the other end. The conductive pattern is not necessarily limited to extending in a straight line, but may extend in complex paths.

The first element group 11 may include at least one element electrically connected to the first high-current path 111 and the second high-current path 112. The first element group 11 may include an integrated sensing/compensation unit 120C.

As illustrated in FIG. 14, the integrated sensing/compensation unit 120C may include at least one choke coil. The choke coil may include a core 123 including a through hole, and conductive windings 1111, 1112, and 124 passing through the through hole or passing through the through hole and then wound around the core 123 at least once. The choke coil may be mounted on one surface of the substrate 10C, and the conductive windings 1111, 1112, and 124 may be electrically connected to a conductive pad P of the substrate 10C and electrically connected to the high-current paths 111 and 112, the first device 300, and the second device 400 through the substrate 10C.

The second element group 12 may include at least one element electrically insulated from the first high-current path 111 and the second high-current path 112 and electrically connected to the first element group 11. The second element group 12 may include a compensation control unit 150C.

The compensation control unit 150C may include a negative impedance converter. In an embodiment, the compensation control unit 150C may be a circuit including at least one amplifier, at least one inductor, at least one capacitor, and at least one resistor. According to an optional embodiment, because the above-described elements of the compensation control unit 150C are implemented as a single IC chip, the volume may be reduced and management may be facilitated. According to an optional embodiment, the at least one amplifier included in the compensation control unit 150C may be implemented as a single IC chip, and inductor, capacitor, and resistor components other than the at least one amplifier may not be implemented as an IC chip. The compensation control unit 150C may be electrically connected to the integrated sensing/compensation unit 120C through the substrate 10C, but the present disclosure is not limited thereto. The compensation control unit 150C may be electrically connected to the integrated sensing/compensation unit 120C directly through the conductive winding of the integrated sensing/compensation unit 120C.

Meanwhile, the compensation control unit 150C may be arranged in any space of the substrate 10C where the choke coil is not arranged. Referring to FIG. 20A, in an embodiment, the compensation control unit 150C may be arranged on the other surface of the substrate 10C where the choke coil is not arranged. Referring to FIG. 20B, in another embodiment, the compensation control unit 150C may be arranged on one surface of the substrate 10C where the choke coil is not arranged. However, FIGS. 20A and 20B are examples, and the concept of the present disclosure is not limited thereto. That is, any arrangement may be utilized as long as the arrangement has the effect of saving space by arranging the compensation control unit 150C connected to the integrated sensing/compensation unit 120C on the other surface or one surface of the substrate 10C, which was previously an empty space, and implementing the active compensation device 100C as a single small device with reduced volume and weight.

FIG. 21 schematically illustrates a structure of an active compensation device 100D according to another embodiment of the present disclosure.

FIG. 21 is a cross-sectional view illustrating the structure of the active compensation device 100D. Descriptions redundant with those provided above with reference to FIGS. 12 to 20, including actively compensating for CM noise and DM noise of each of the two or more high-current paths 111 and 112, are omitted, and the structure of the active compensation device 100D is mainly described.

Referring to FIG. 21, the active compensation device 100D may include a substrate 10D, and a first element group 11 and a second element group 12 provided in the substrate 10D.

The active compensation device 100D of FIG. 21 includes at least two integrated sensing/compensation units (a first integrated sensing/compensation unit 120D1, a second integrated sensing/compensation unit 120D2, etc.) in the first element group 11. In addition, the second element group 12 may include at least two compensation control units (a first compensation control unit (not shown), a second compensation control unit (not shown), etc.). Here, because the at least two compensation control units are implemented as a single IC chip 150D, the volume may be reduced and management may be facilitated.

According to an embodiment, the single IC chip 150D including the at least two compensation control units may be arranged in any space of the substrate 10D where the integrated sensing/compensation units 120D1 and 120D2 are not arranged. FIG. 21 illustrates that the IC chip 150D is arranged on the other surface of the substrate 10D where the integrated sensing/compensation units 120D1 and 120D2 are not arranged, but this is an example, and the concept of the present disclosure is not limited thereto.

Meanwhile, the at least two integrated sensing/compensation units may sense both CM noise and DM noise. However, according to an optional embodiment, the at least two integrated sensing/compensation units may sense different modes of noises. For example, a first choke coil of the first integrated sensing/compensation unit 120D1 may sense CM noise and may be activated by a compensation voltage output from the first compensation control unit, so that the effective impedance is increased. A second choke coil of the second integrated sensing/compensation unit 120D2 may sense DM noise and may be activated by a compensation voltage output from the second compensation control unit, so that the effective impedance is increased. Even in this case, because the first compensation control unit and the second compensation control unit are implemented as a single IC chip 150D, the volume may be reduced and management may be facilitated.

Meanwhile, according to an optional embodiment, only the amplifier (OP-amp) among the components of the at least two compensation control units may be implemented as the single IC chip 150D. In this case, the inductor, capacitor, and resistor components other than the amplifier may not be implemented as an IC chip. The IC chip 150D may be electrically connected to the integrated sensing/compensation units 120D1 and 120D2 through the substrate 10D, but the present disclosure is not limited thereto. The IC chip 150D may be electrically connected to the integrated sensing/compensation unit 120C directly through the conductive windings of the integrated sensing/compensation units 120D1 and 120D2.

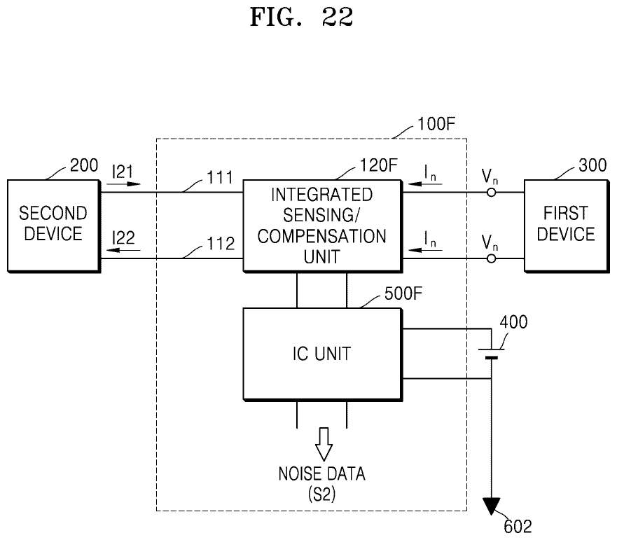

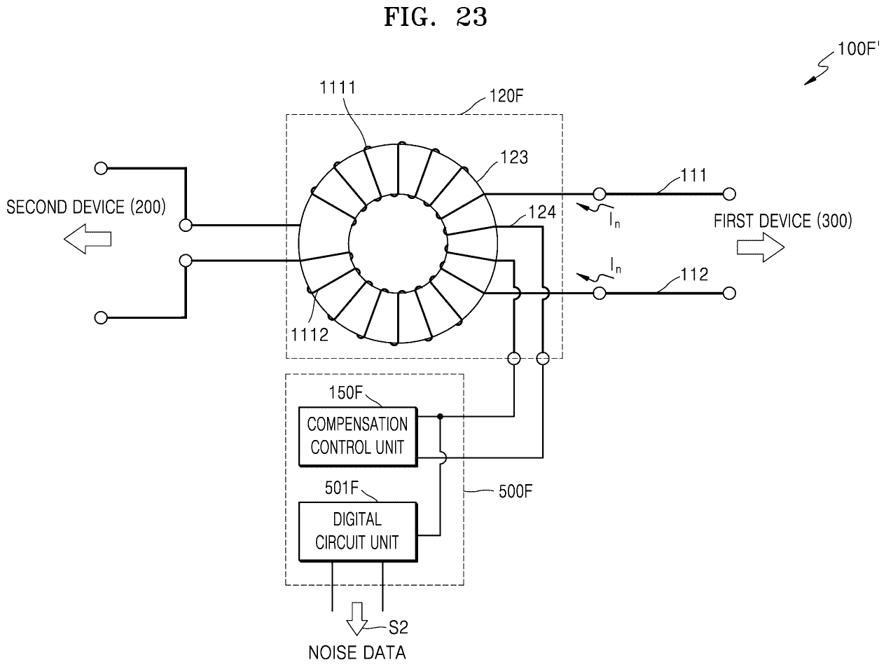

FIG. 22 schematically illustrates a configuration of a system including an active compensation device 100F, according to another embodiment of the present disclosure. FIG. 23 schematically illustrates a detailed example of the active compensation device 100F of FIG. 22, according to an embodiment of the present disclosure.

Referring to FIGS. 22 and 23, the active compensation device 100F may include an integrated sensing/compensation unit 120F and an IC unit 500F. The active compensation device 100F illustrated in FIGS. 22 and 23 includes the integrated sensing/compensation unit 120F, similar to the active compensation device 100 illustrated in FIG. 12, but the compensation control unit 150F is integrated with a digital circuit unit 501F and provided within the IC unit 500F.

The integrated sensing/compensation unit 120F may refer to a means for sensing at least one of CM noise and DM noise on high-current paths 111 and 112. The integrated sensing/compensation unit 120F may include a choke coil. The choke coil may include a conductor 123 including a through hole, and conductive windings passing through the through hole or passing through the through hole and then wound around the conductor 123 at least once. The conductive windings may include at least two high-current path windings 1111 and 1112 and a sensing/compensation winding 124.

The integrated sensing/compensation unit 120F illustrated in FIG. 23 is similar to the integrated sensing/compensation unit 120 illustrated in FIG. 15D in that the number of turns of the high-current path winding 1111 is equal to the number of turns of the high-current path winding 1112, but the winding direction of the high-current path winding 1111 is different from the winding direction of the high-current path winding 1112. However, the integrated sensing/compensation unit 120F may employ not only the choke coil illustrated in FIG. 23, but also one of the choke coils illustrated in FIGS. 14, 15A, 15B, 15C, and 15E. Because the integrated sensing/compensation unit 120F illustrated in FIGS. 22 and 23 is substantially the same as the integrated sensing/compensation unit 120 illustrated in FIGS. 12 to 15E, the descriptions provided with reference to FIGS. 12 to 15E are applicable to the integrated sensing/compensation unit 120F illustrated in FIGS. 22 and 23.

Meanwhile, the integrated sensing/compensation unit 120F senses at least one of CM noise and DM noise on the two or more high-current paths 111 and 112 and provides a corresponding sensing signal to the IC unit 500F. The IC unit 500F may include the compensation control unit 150F and the digital circuit unit 501F. A signal input to the IC unit 500F may be input to each of the compensation control unit 150F and the digital circuit unit 501F.

The compensation control unit 150F may be electrically connected to the integrated sensing/compensation unit 120F through the sensing/compensation winding 124, receive a sensing signal corresponding to the sensed noise from the integrated sensing/compensation unit 120F, generate a compensation signal, and transfer the compensation signal to the integrated sensing/compensation unit 120F through the sensing/compensation winding 124. In the active compensation device 120F of FIGS. 22 and 23, noise sensing and noise compensation are performed at the same location. That is, in the active compensation device 120F of FIGS. 22 and 23, an induced voltage Vₛₑₙ corresponding to the sensing signal is induced at a terminal node of the sensing/compensation winding 124 by the integrated sensing/compensation unit 120F, and a compensation voltage is induced at a terminal node of the sensing/compensation winding 124 by the compensation control unit 150F. The integrated sensing/compensation unit 120F may be connected to the high-current paths 111 and 112, and the compensation control unit 150F may be insulated from the high-current paths 111 and 112. The compensation control unit 150F of FIGS. 22 and 23 is substantially the same as the compensation control unit 150 of FIGS. 12 to 19 according to an embodiment. Accordingly, the descriptions provided with reference to FIGS. 12 to 19 are applicable to the compensation control unit 150F of FIGS. 22 and 23.

The digital circuit unit 501F may output noise data S2 based on a signal (e.g., Vₛₑₙ) input from the integrated sensing/compensation unit 120F. The digital circuit unit 501F is substantially the same as the digital circuit unit 501 described with reference to FIGS. 2 to 6. Accordingly, the descriptions provided with reference to FIGS. 2 to 6 are applicable to the digital circuit unit 501F of FIGS. 22 and 23.

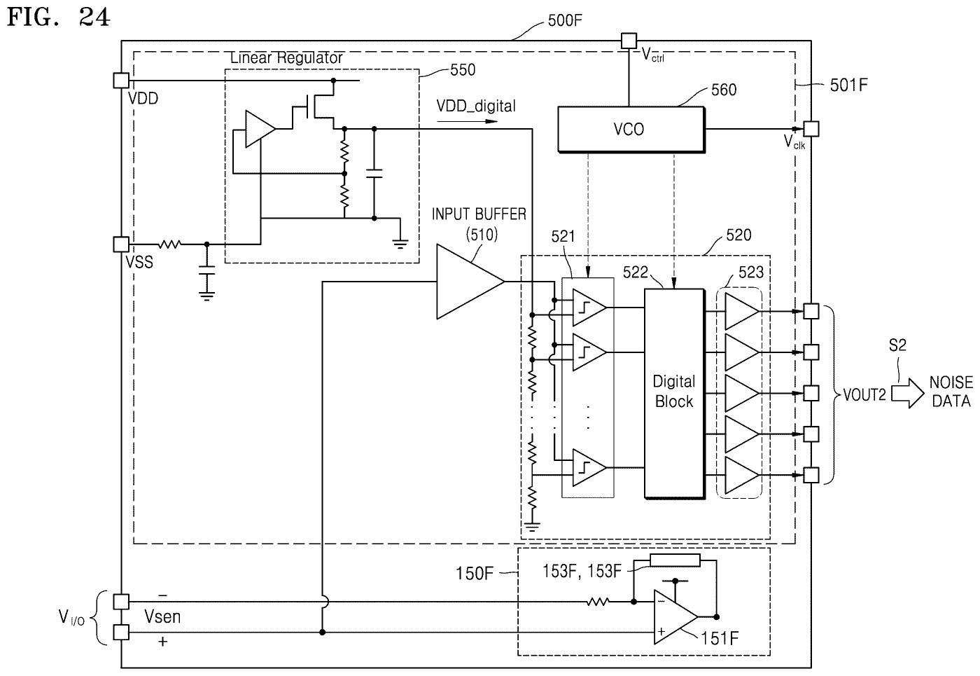

FIG. 24 illustrates a detailed example of an IC unit 500F, according to various embodiments of the present disclosure.

The IC unit 500F of FIG. 24 includes a compensation control unit 150F instead of the amplification unit 130, compared to the IC unit 500 illustrated in FIG. 3. That is, the IC unit 500F includes the compensation control unit 150F and a digital circuit unit 501F that are embedded therein to form a single IC chip. In addition, the single IC chip may include an input/output terminal V_{I/O} that receives a sensing signal from an integrated sensing/compensation unit 120F and outputs a compensation signal, and an output terminal VOUT2 that outputs noise data S2.

The digital circuit unit 501F of FIG. 24 is substantially the same as the digital circuit unit 501 illustrated in FIG. 3, except that the noise data S2 is output based on the signal (e.g., Vₛₑₙ) input from the integrated sensing/compensation unit 120F. The digital circuit unit 501F of FIG. 24 may include an analog-to-digital converter (ADC) 520 and an input buffer 510 that receives a sensing signal and attenuates the sensing signal into a low-voltage analog signal that is usable for the ADC 520. In addition, the digital circuit unit 501F may further include a voltage-controlled oscillator 560 that independently generates a clock signal for controlling the internal circuit of the ADC 520. The descriptions of the components of the digital circuit unit 501 illustrated in FIG. 3, to which the same reference numerals are assigned, are applicable to the remaining components included in the digital circuit unit 501F of FIG. 24.

The compensation control unit 150F illustrated in FIG. 24 differs from the compensation control units 150 and 150A described with reference to FIGS. 13, 17, and 18 in some components, but the functions or roles thereof are substantially the same as each other. The compensation control unit 150F may be a component that provides negative impedance. In addition, the compensation control unit 150F may include an amplification unit 151F that generates an amplified signal corresponding to the sensed noise, a target unit 152F that generates a compensation signal corresponding to the amplified signal, and a stabilization unit 153F that is connected to the target unit 152F and prevents oscillation caused by the sensed noise. The magnitude of the impedance of the target unit 152F and the stabilization unit 153F is greater than the magnitude of the total input impedance viewed from the compensation control unit 150F toward the integrated sensing/compensation unit 120F. In addition, the descriptions of the compensation control units 150 and 150A with reference to FIGS. 13, 17, and 18 are applicable to the compensation control unit 150F.

According to the embodiments of FIGS. 22 to 24, the active compensation device 100F includes the compensation control unit 150F and the digital circuit unit 501F embedded in the IC unit 500F, and the digital circuit unit 501F generates the noise data S2 based on the signal Vₛₑₙ input from the integrated sensing/compensation unit 120F. Accordingly, there is an effect that may be utilized not only for simple noise compensation and reduction operations but also for feedback control through noise monitoring and, additionally, for system control through suitability monitoring.

According to various embodiments of the present disclosure described with reference to FIGS. 12 to 24, it is possible to provide an active compensation device that reduces both CM noise and DM noise without significantly increasing the price, area, volume, or weight.

In addition, the active compensation device according to various embodiments described with reference to FIGS. 12 to 24 may implement a stable noise reduction operation by preventing oscillation that generates an unwanted frequency peak signal due to resonance that may occur in the noise compensation process.

In addition, the active compensation device according to various embodiments described with reference to FIGS. 12 to 24 does not need to have a common ground with the power line, and thus, may be utilized in low-power home appliances, such as monitor adapters or display chargers, or two-prong home appliances.

Moreover, the active compensation device according to various embodiments described with reference to FIGS. 12 to 24 may be reduced in price, area, volume, and weight, compared to a passive compensation device including a bulky and heavy CM choke.

According to various embodiments of the present disclosure, noise data may be extracted and collected from an active compensation device, and used for various purposes. For example, noise data output from the active compensation device according to an embodiment of the present disclosure may be monitored to identify a change in state or an emergency situation. Also, the noise data may be utilized for big data processing.

Although the present disclosure has been described with reference to the embodiments illustrated in the drawings, they are merely exemplary, and it will be understood by one of skill in the art that various modifications and equivalent embodiments may be made therefrom. Therefore, the true technical protection scope of the present disclosure should be determined by the appended claims.

### INDUSTRIAL APPLICABILITY

Embodiments of the present disclosure may be used in electronic devices such as household electrical appliances, industrial electrical appliances, electric vehicles, airplanes, energy storage systems, etc. However, the industrial applicability according to embodiments of the present disclosure is not limited thereto.

1. An active compensation device comprising:
an integrated sensing/compensation unit configured to generate a sensing signal corresponding to at least one of common-mode noise and differential-mode noise on at least two high-current paths; and
a compensation control unit comprising a negative impedance converter and configured to generate a compensation signal corresponding to the sensing signal and provide the compensation signal to the integrated sensing/compensation unit,
wherein the compensation control unit further comprises a stabilization unit configured to prevent oscillation caused by the sensed noise.

2. The active compensation device of claim 1, wherein the integrated sensing/compensation unit comprises a choke coil comprising:
a conductor comprising a through hole;
at least two high-current path windings passing through at least the through hole and connected to each of the at least two high-current paths; and
a sensing/compensation winding insulated from the at least two high-current paths and passing through at least the through hole,
wherein the at least two high-current path windings are each asymmetrically wound around the conductor.

3. The active compensation device of claim 2, wherein the integrated sensing/compensation unit is further configured to provide the sensing signal corresponding to the noise to the compensation control unit through the sensing/compensation winding, and
the compensation control unit is further configured to provide the compensation signal to the integrated sensing/compensation unit through the sensing/compensation winding.

4. The active compensation device of claim 2, wherein the choke coil comprises:
a primary side on which the at least two high-current path windings are arranged; and
a secondary side on which the sensing/compensation winding is arranged,
wherein a voltage induced on the secondary side is generated as the sensing signal, based on a magnetic field induced by noise on the primary side.

5. The active compensation device of claim 2, wherein the at least two high-current path windings have different numbers of turns, respectively.

6. The active compensation device of claim 2, wherein the at least two high-current path windings have different degrees of winding density, respectively.

7. The active compensation device of claim 2, wherein the at least two high-current path windings have different winding angles, respectively.

8. The active compensation device of claim 2, wherein the at least two high-current path windings are different from each other in overlap winding.

9. The active compensation device of claim 2, wherein the at least two high-current path windings has a different number of overlaps when overlapped.

10. The active compensation device of claim 1, wherein the integrated sensing/compensation unit is connected to the at least two high-current paths, and
the compensation control unit is insulated from the at least two high-current paths.

11. The active compensation device of claim 1, wherein the compensation control unit further comprises:
an amplification unit configured to generate an amplified signal corresponding to the sensing signal; and
a target unit configured to generate the compensation signal corresponding to the amplified signal,
the stabilization unit is connected to the target unit, and
a magnitude of impedance of the target unit and the stabilization unit is greater than a magnitude of total input impedance viewed from the compensation control unit toward the integrated sensing/compensation unit.

12. The active compensation device of claim 1, wherein the compensation control unit comprises at least one amplifier, and the at least one amplifier is implemented as a single integrated chip.

13. The active compensation device of claim 1, further comprising an integrated circuit (IC) unit comprising a digital circuit unit configured to output noise data into which the sensing signal from the integrated sensing/compensation unit is digitally converted,
wherein the compensation control unit is embedded in the IC unit.

14. The active compensation device of claim 13, wherein the IC unit is composed of a single IC chip, and the single IC chip comprises:
an input/output terminal to receive the sensing signal from the integrated sensing/compensation unit and output the compensation signal; and
an output terminal to output the noise data.

15. The active compensation device of claim 13, wherein the digital circuit unit comprises:
an analog-to-digital converter; and
an input buffer configured to receive the sensing signal and attenuate the sensing signal into a low-voltage analog signal that is usable for the analog-to-digital converter.

16. The active compensation device of claim 15, wherein the IC unit further comprises a voltage-controlled oscillator configured to independently generate a clock signal for controlling an internal circuit of the analog-to-digital converter.

17. A noise reduction method of the active compensation device of claim 2, the noise reduction method comprising:
sensing, by the active compensation device, at least one of common-mode noise and differential-mode noise on the at least two high-current paths; and
based on a sensing signal generated in a sensing/compensation winding due to the noise, generating, by the active compensation device, a compensation signal corresponding to the sensing signal and applying the compensation signal to the sensing/compensation winding so that a choke coil is activated to reduce the noise.

18. The noise reduction method of claim 17, wherein the active compensation device converts the sensing signal into the compensation signal according to impedance of each of a target unit and the stabilization unit included in the active compensation device.
